(19) United States
(12) Patent Application Publication
(10) Pub. No.: US 2026/0271436 A1
(43) Pub. Date: Sep. 10, 2026

(54) DISPLAY DEVICE, METHOD FOR MANUFACTURING THE SAME AND ELECTRONIC DEVICE

(71) Applicant: Samsung Display Co., Ltd., Yongin-si (KR)

(72) Inventor: Hye Lim KANG, Yongin-si (KR)

(21) Appl. No.: 19/431,003

(22) Filed: Dec. 23, 2025

(30) Foreign Application Priority Data
Mar. 6, 2025 (KR) 10-2025-0028951
Apr. 10, 2025 (KR) 10-2025-0046891

(51) Int. Cl. H10H 20/82; H10H 20/01; H10H 20/831; H10H 20/84; H10H 29/49

(52) U.S. Cl. CPC H10H 20/82; H10H 20/017; H10H 20/034; H10H 20/0364; H10H 20/8312; H10H 20/84; H10H 29/49

(57) ABSTRACT

A display device, a method for manufacturing the same, and an electronic device are provided. A display device includes: a substrate; a first pixel electrode and a second common electrode spaced from each other on the substrate; and a light emitting element on the first pixel electrode and the second common electrode, the light emitting element having a plurality of roughness patterns on a side surface, wherein the light emitting element is divided into a plurality of regions along a direction perpendicular to the substrate, and sizes of the plurality of roughness patterns in the plurality of regions are different from each other.

### CROSS-REFERENCE TO RELATED APPLICATION

This application claims priority to, and the benefit of, Korean Patent Application No. 10-2025-0028951, filed on Mar. 6, 2025 and Korean Patent Application No. 10-2025-0046891, filed on Apr. 10, 2025, the entire disclosure of all of which is incorporated by reference herein.

### BACKGROUND

### 1. Field

The present disclosure relates to a display device, a method for manufacturing the same, and an electronic device.

### 2. Description of the Related Art

With the development of the information society, the demand for display devices for displaying images is increasing in various forms. The display device may be a flat panel display such as a liquid crystal display, a field emission display, a light emitting display, and/or the like.

The light emitting display device may be implemented as an organic light emitting display device including an organic light emitting diode (OLED) element as the light emitting element, an inorganic light emitting display device including an inorganic semiconductor element as the light emitting element, or a ultra-small light emitting diode display device including a ultra-small light emitting diode element (or micro light emitting diode element) as the light emitting element.

### SUMMARY

Aspects and features of embodiments of the present disclosure are to provide a display device capable of increasing the light emission efficiency of a light emitting element and a manufacturing method thereof.

However, aspects and features of embodiments of the present disclosure are not restricted to the one set forth herein. The above and other aspects and features of embodiments of the present disclosure will become more apparent to one of ordinary skill in the art to which the present disclosure pertains by referencing the detailed description of the present disclosure given below.

According to one or more embodiments of the present disclosure, a display device includes: a substrate; a first pixel electrode and a second common electrode spaced from each other on the substrate; and a light emitting element on the first pixel electrode and the second common electrode, the light emitting element having a plurality of roughness patterns on a side surface, wherein the light emitting element is divided into a plurality of regions along a direction perpendicular to the substrate, and sizes of the plurality of roughness patterns in the plurality of regions are different from each other.

In one or more embodiments, the plurality of regions include a first region and a second region, wherein the light emitting element includes a first semiconductor layer, an active layer, and a second semiconductor layer, wherein the first region includes the first semiconductor layer and the active layer, and wherein a size of a roughness pattern of the first region is smaller than a size of a roughness pattern of the second region.

In one or more embodiments, the plurality of regions further include a third region, wherein the first region, the second region, and the third region are arranged sequentially, and wherein the sizes of the plurality of roughness patterns increases from the first region to the third region.

In one or more embodiments, the size of the roughness pattern of the first region is 1 μm or less, wherein the size of the roughness pattern of the second region is more than 1 μm and 3 μm or less, and wherein a size of the roughness pattern of the third region is 3 μm or more.

In one or more embodiments, the plurality of roughness patterns has a protrusion shape that becomes thinner toward outside, or has an irregular pattern shape in which a width and a height of the protrusion shape are randomly distributed.

In one or more embodiments, a shape of the roughness pattern of the first region and a shape of the roughness pattern of the second region are different from each other.

In one or more embodiments, the light emitting element includes: a plurality of semiconductor layers; a first contact electrode extending laterally from one surface of the light emitting element; and a second contact electrode extending laterally from the one surface of the light emitting element, the second contact electrode being spaced from the first contact electrode, wherein the first contact electrode and the second contact electrode are in the first region and the second region.

In one or more embodiments, the display device further includes: an organic layer between the light emitting element, and the first pixel electrode and the second common electrode; a first connection electrode electrically connecting the first pixel electrode and the first contact electrode; and a second connection electrode electrically connecting the second common electrode and the second contact electrode.

In one or more embodiments, the light emitting element further includes: a conductive layer on an element planarization layer; and a protective film on one surface and side surfaces of the conductive layer and side surfaces of the plurality of semiconductor layers, wherein the first contact electrode is on the protective film and is connected to the conductive layer exposed without being covered by the protective film, and wherein the second contact electrode is on the protective film and is located in a hole penetrating the conductive layer and a portion of the plurality of semiconductor layers.

In one or more embodiments, a side corresponding to the first region of the light emitting element is surrounded by the organic layer, and at least a portion of the side is outside the organic layer.

In one or more embodiments, the display device further includes a via layer covering the first connection electrode and the second connection electrode, wherein the first region and the second region are surrounded by the via layer.

In one or more embodiments, a top surface of the light emitting element has a concave pattern light extraction pattern having a cross-sectional shape of a semicircle or a semi-ellipse.

In one or more embodiments, a method for manufacturing a display device including a light emitting element, the method including: forming a third semiconductor material layer, a second semiconductor material layer, an active material layer, a first semiconductor material layer, and a conductive material layer on a semiconductor substrate; etching the active material layer, the first semiconductor material layer, and the conductive material layer to form a first element rod having a first roughness pattern on a side surface; forming a protective film to protect the first element rod; forming a mask covering the first element rod and etching the second semiconductor material layer and the third semiconductor material layer to form a second element rod having a second roughness pattern; and forming a first contact electrode and a second contact electrode extending laterally from one surface of the first element rod, the first contact electrode and the second contact electrode being spaced from each other, wherein a size of the second roughness pattern is different from a size of the first roughness pattern.

In one or more embodiments, a size of the first roughness pattern is smaller than a size of the second roughness pattern.

In one or more embodiments, the first roughness pattern and the second roughness pattern have a protrusion shape that becomes thinner toward outside or have an irregular pattern shape in which a width and height of the protrusion shape are randomly distributed.

In one or more embodiments, the first element rod is formed by wet etching, and wherein the second element rod is formed by wet etching or dry etching.

In one or more embodiments, the method further includes: transferring the light emitting element to a backplane substrate so that the first contact electrode and the second contact electrode face a pixel electrode and a common electrode of the backplane substrate; forming a first connection electrode connecting the pixel electrode and the first contact electrode of the light emitting element, and a second connection electrode connecting the common electrode and the second contact electrode of the light emitting element; and forming a via layer covering the first connection electrode and the second connection electrode.

In one or more embodiments, an organic layer is formed on the pixel electrode and the common electrode of the backplane substrate, wherein the side surface of the first element rod is buried in the organic layer, a portion of a side surface of the first contact electrode of the light emitting element and a portion of a side surface of the second contact electrode are embedded in the organic layer, and a remaining portion of the side surface of the first contact electrode and a remaining portion of the side surface of the second contact electrode are not covered by the organic layer.

In one or more embodiments, the first connection electrode is connected to a remaining portion of the side surface of the first contact electrode, and the second connection electrode is connected to a remaining portion of the side surface of the second contact electrode.

In one or more embodiments, an electronic device includes: a display panel; a window arranged on the display panel; and a bottom cover arranged below the display panel, wherein the display panel includes: a substrate; a first electrode and a second electrode spaced from each other on the substrate; and a light emitting element on the first electrode and the second electrode, the light emitting element having a plurality of roughness patterns on a side surface, wherein the light emitting element is divided into a plurality of regions along a direction perpendicular to the substrate, and sizes of the roughness patterns in the plurality of regions are different from each other.

A display device and the manufacturing method thereof according to one or more embodiments, the light emission efficiency of a light emitting element may be improved.

However, the present disclosure is not limited to the aforementioned effects, aspects, and features, and various other aspects are included in the present specification.

### BRIEF DESCRIPTION OF THE DRAWINGS

FIG. 1 is a perspective view illustrating a display device according to one or more embodiments.

FIG. 2 is a layout diagram illustrating a display device according to one or more embodiments.

FIG. 3 is a block diagram illustrating a display device according to one or more embodiments.

FIG. 4 is an equivalent circuit diagram illustrating a sub-pixel according to one or more embodiments.

FIG. 5 is a layout diagram illustrating pixels of a display area according to one or more embodiments.

FIG. 6 is a cross-sectional view illustrating an example cross-section of one display panel corresponding to the lines I1-I1′ in FIG. 5.

FIG. 7 is a cross-sectional view illustrating an example of an area A in FIG. 6 in detail.

FIG. 8 is an enlarged cross-sectional view of a semiconductor layer of a light emitting element of FIG. 7.

FIG. 9 is an enlarged cross-sectional view of the semiconductor layer of the light emitting element of FIG. 7 according to another embodiment.

FIG. 10 and FIG. 11 are enlarged cross-sectional views of the semiconductor layer of the light emitting element of FIG. 7 according to another embodiment.

FIG. 12 is a cross-sectional view illustrating in detail an example of the area A of FIG. 6 according to another embodiment.

FIG. 13 is an enlarged cross-sectional view of a semiconductor layer of a light emitting element of FIG. 12.

FIG. 14 is a layout diagram illustrating pixels of a display area according to one or more embodiments.

FIG. 15 is a cross-sectional view illustrating an example of a cross-section of a display panel corresponding to the line I2-I2′ of FIG. 14.

FIG. 16 is a cross-sectional view illustrating in detail an example of an area B area of FIG. 15.

FIG. 17 is an enlarged cross-sectional view of a plurality of semiconductor layers of a light emitting element of FIG. 16.

FIG. 18 is a flowchart illustrating a method of manufacturing a display device according to one or more embodiments.

FIG. 19-31 are example drawings illustrating a method of manufacturing a display device according to one or more embodiments.

FIG. 32 is a photograph of a plan view and a perspective view of a light emitting element formed with reference to FIG. 18-31.

FIGS. 33 and 34 are example drawings illustrating a smart watch including a display device according to one or more embodiments.

FIG. 35 is an exploded perspective view of a smart watch including a display device according to one or more embodiments.

FIG. 36 is example views of a virtual reality (VR) device including a display device according to one or more embodiments.

FIG. 37 is an example view of a VR device including a display device according to one or more embodiments.

FIG. 38 is an example view illustrating a vehicle instrument cluster and center fascia including display devices according to one or more embodiments.

FIG. 39 is an example view of a transparent display device including a display device according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit and/or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and/or hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure are described with reference to the drawings.

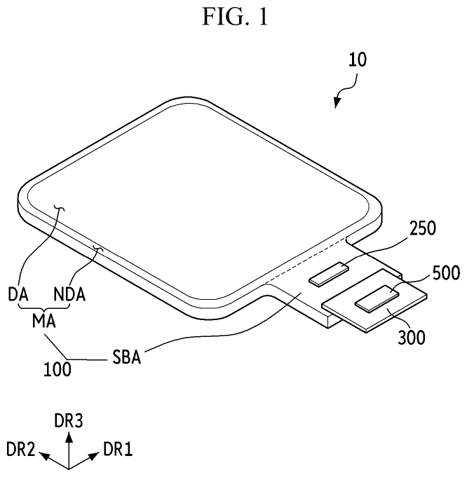

FIG. 1 is a schematic perspective view illustrating a display device according to one or more embodiments.

Referring to FIG. 1, a display device 10 may be for displaying video or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and ultra mobile PC (UMPC), as well as display screens for a variety of products such as televisions, laptops, monitors, billboards, and/or the internet of things (IOT).

The display device 10 may be a light emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the disclosure is not limited thereto. On the other hand, hereinafter, an ultra-small light emitting diode is described as a light emitting element for convenience of explanation.

The display device 10 may include a display panel 100, a display driving circuit 250, a circuit substrate 300, and a power supply circuit (e.g., a power supply unit) 500.

The display panel 100 may be formed as a rectangular shaped plane having a short side in the first direction DR1 and a long side in the second direction DR2 that intersects the first direction DR1. A corner where the short side in the first direction DR1 and the long side in the second direction DR2 meet may be rounded to have a suitable curvature (e.g., a selected or predetermined curvature) or may be formed at a right angle. The planar shape of the display panel 100 is not limited to a rectangle, but may be formed in other polygonal, circular, or oval shapes. The display panel 100 may be formed flat but is not limited thereto. For example, the display panel 100 may be formed at the left and right ends and may include curved portions with a constant curvature or a changing curvature. The display panel 100 may be flexibly formed to be bent, curved, bent, folded, and/or rolled.

The substrate SUB of the display panel 100 may include a main area MA and a sub-area SBA.

The main area MA may include a display area DA that displays an image and a non-display area NDA that is a surrounding area of the display area DA. The display area DA may include multiple pixels that display an image. Each pixel may include multiple sub-pixels. For example, each of the pixels may include a first sub-pixel that emits light of a first color, a second sub-pixel that emits light of a second color, and a third sub-pixel that emits light of a third color. However, the present disclosure is not limited thereto.

The sub-area SBA may protrude from a side of the main area MA in the second direction DR2. Although FIG. 1 illustrates the sub-area SBA being unfolded, the sub-area SBA may be bent, and for example, may be disposed on the lower surface of the display panel 100. In case that the sub-area SBA is bent, it may overlap the main area MA in the third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the display panel 100 using a chip on glass (COG) method, a chip on plastic (COP) method, or an ultrasonic bonding method but is not limited thereto. The display driving circuit 250 may be attached to the circuit substrate 300 using a chip on film (COF) method.

The circuit substrate 300 may be attached to an end of the sub-area SBA of the display panel 100. For example, the circuit substrate 300 may be electrically connected to the display panel 100 and the display driving circuit 250. The display panel 100 and the display driving circuit 250 may receive digital video data, timing signals, and driving voltages through the circuit substrate 300. The circuit substrate 300 may be a flexible film, such as a flexible printed circuit substrate, a printed circuit substrate, or a chip on film.

The power supply circuit 500 may generate multiple panel driving voltages according to an external power supply voltage. The power supply circuit 500 may be formed as an integrated circuit (IC) and attached to the circuit substrate 300 using a COF method.

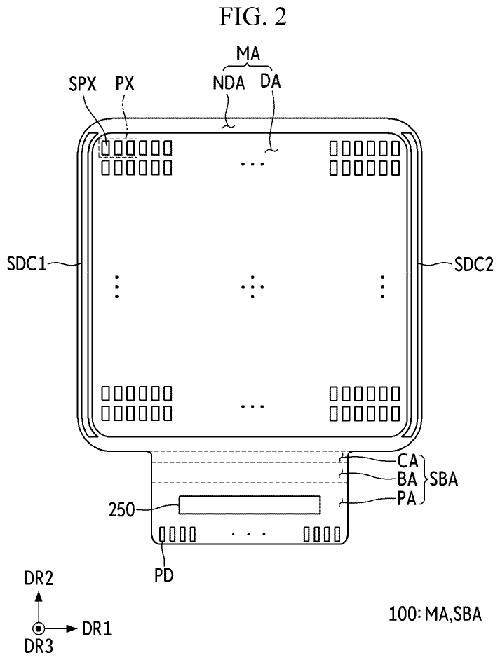

FIG. 2 is a schematic layout illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be disposed in the center of the main area MA.

The display area DA may include multiple pixels PX for displaying an image, and each of multiple pixels PX may include multiple sub-pixels SPX. A pixel PX may be defined as a sub-pixel group of the smallest unit capable of expressing a white gray level (e.g., a white grayscale value).

The non-display area NDA may be disposed adjacent to the display area DA. The non-display area NDA may be an area disposed outside the display area DA. The non-display area NDA may be around (e.g., may surround) the display area DA. The non-display area NDA may be an edge area of the display panel 100.

A first scan driving portion SDC1 and a second scan driving portion SDC2 may be disposed in the non-display area NDA. The first scan driving portion SDC1 may be disposed on a side (e.g., the left side) of the display panel 100, and the second scan driving portion SDC2 may be disposed on another side (e.g., the right side) of the display panel 100 but are not limited thereto. Each of the first scan driving portion SDC1 and the second scan driving portion SDC2 may be electrically connected to the display driving circuit 250 through scan fan out lines. Each of the first scan driving portion SDC1 and the second scan driving portion SDC2 may receive a scan control signal from the display driving circuit 250, generate scan signals according to the scan control signal, and output them to scan lines.

The sub-area SBA may protrude from a side of the main area MA in the second direction DR2. The length of the sub-area SBA in the second direction DR2 may be smaller than the length of the main area MA in the second direction DR2. The length in the first direction DR1 of the sub-area SBA may be less than the length in the first direction DR1 of the main area MA or may be substantially equal to the length in the first direction DR1 of the main area MA. The sub-area SBA may be curved and may be disposed at a lower portion of the display panel 100. For example, the sub-area SBA may overlap the main area MA in the third direction DR3.

The sub-area SBA may include a connection area CA, a pad area PA, and a bending area BA.

The connection area CA may be an area protruding from a side of the main area MA in the second direction DR2. A side of the connection area CA may be in contact with the non-display area NDA of the main area MA, and another side of the connection area CA may be in contact with the bending area BA.

The pad area PA may be an area where the pads PD and the display driving circuit 250 may be disposed. The display driving circuit 250 may be attached to the driving pads of the pad area PA using a conductive adhesive member such as an anisotropic conductive film. The circuit substrate 300 may be attached to the pads PD of the pad area PA using a conductive adhesive member such as an anisotropic conductive film. A side of the pad area PA may be in contact with the bending area BA.

The bending area BA may be a bent area. In case that the bending area BA is bent, the pad area PA may be disposed below the connection area CA and below the main area MA. The bending area BA may be disposed between the connection area CA and the pad area PA. A side of the bending area BA may be in contact with the connection area CA, and another side of the bending area BA may be in contact with the pad area PA.

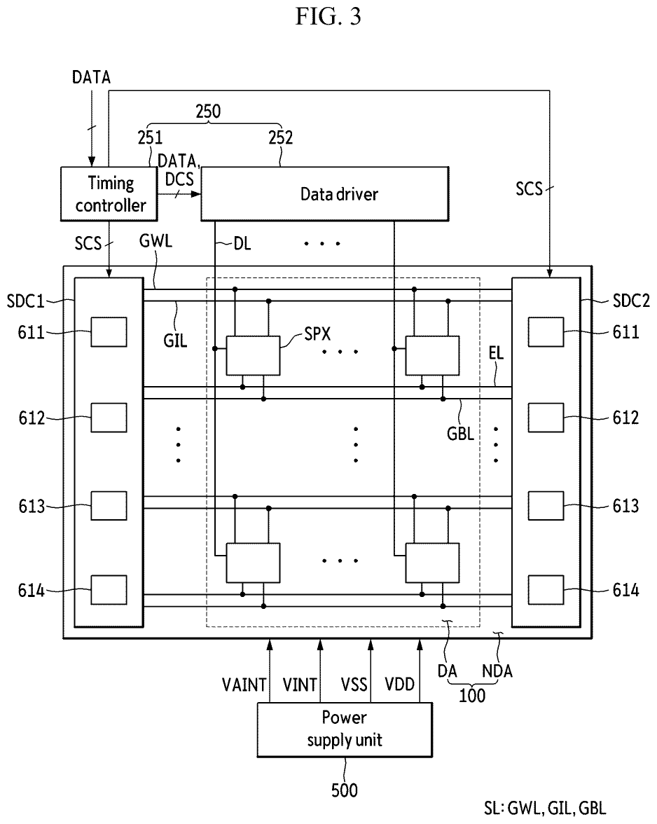

FIG. 3 is a schematic block diagram illustrating a display device according to one or more embodiments.

Referring to FIG. 3, the display area DA may include multiple pixels PX (each of the pixels PX including a plurality of sub-pixel SPX), multiple scan lines SL, multiple emission control lines EL, and multiple data lines DL.

Multiple pixels PX may be arranged in a matrix form along the first direction DR1 and the second direction DR2. For example, the plurality of pixels PX may be arranged along rows and columns of a matrix along the first direction DR1 and the second direction DR2. Multiple scan lines SL and multiple emission control lines EL may extend in the first direction DR1 and be disposed along the second direction DR2. Multiple data lines DL may extend in the second direction DR2 and be disposed along the first direction DR1. Multiple scan lines SL may include a multiple write scan lines GWL, multiple initialization scan lines GIL, and multiple bias scan lines GBL.

Each of multiple sub-pixels SPX may be electrically connected to a write scan line GWL from among multiple write scan lines GWL, an initialization scan line GIL from among multiple initialization scan lines GIL, a bias scan line GBL from among multiple bias scan lines GBL, an emission control line EL from among multiple emission control lines EL, and a data line DL from among multiple data lines DL. Each of multiple sub-pixels SPX may be supplied with a data voltage of the data line DL according to the write scan signal of the write scan line GWL and may emit light emitting elements according to the data voltage.

The non-display area NDA may include a first scan driving portion SDC1, a second scan driving portion SDC2, and a display driving circuit 250.

Each of the first scan driving portion SDC1 and the second scan driving portion SDC2 may include a write scan signal output portion 611, an initialization scan signal output portion 612, a bias scan signal output portion 613, and an emission control signal output portion 614. Each of the write scan signal output portion 611, the initialization scan signal output portion 612, the bias scan signal output portion 613, and the emission control signal output portion 614 may receive a scan timing control signal SCS from a timing control circuit (e.g., a timing controller) 251.

The write scan signal output portion 611 may generate write scan signals according to the scan timing control signal SCS of the timing control circuit 251 and sequentially output them to the write scan lines GWL.

The initialization scan signal output portion 612 may generate initialization scan signals according to the scan timing control signal SCS and sequentially output them to the initialization scan lines GIL.

The bias scan signal output portion 613 may generate bias scan signals according to the scan timing control signal SCS and sequentially output them to the bias scan lines GBL. The emission control signal output portion 614 may generate emission control signals according to the scan timing control signal SCS and sequentially output them to the emission control lines EL.

The display driving circuit 250 may include a timing control circuit (e.g., a timing controller) 251 and a data driving circuit (e.g., a data driver) 252.

The data driving circuit 252 may receive digital video data DATA and a data timing control signal DCS from the timing control circuit 251. The data driving circuit 252 converts digital video data DATA into analog data voltages according to the data timing control signal DCS and outputs them to the data lines DL. For example, the sub-pixels SPX may be selected by the write scan signals of the first scan driving portion SDC1 and the second scan driving portion SDC2, and data voltages may be supplied to the selected sub-pixels SPX.

The timing control circuit 251 may receive digital video data DATA and timing signals from the outside. The timing control circuit 251 may generate a scan timing control signal SCS and a data timing control signal DCS for controlling the display panel 100 according to the timing signals. The timing control circuit 400 may output the scan timing control signal SCS to the first scan driving portion SDC1 and the second scan driving portion SDC2. The timing control circuit 251 may output digital video data DATA and a data timing control signal DCS to the data driving circuit 252.

The power supply circuit (e.g., a power supply unit) 500 may generate multiple panel driving voltages according to a power voltage supplied from the outside. For example, the power supply circuit 500 may generate a first power supply voltage VDD, a second power supply voltage VSS, a third power supply voltage VINT, and a fourth power supply voltage VAINT and supply them to the display panel 100.

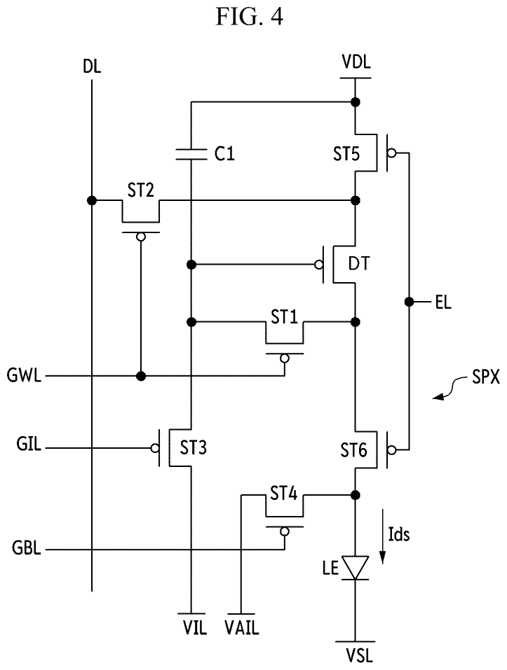

FIG. 4 is a schematic diagram of an equivalent circuit of a sub-pixel according to one or more embodiments.

Referring to FIG. 4, a sub-pixel SPX according to one or more embodiments may be electrically connected to scan lines GWL, GIL, and GBL, an emission control line EL, and a data line DL. For example, the sub-pixel SPX may be electrically connected to a write scan line GWL, an initialization scan line GIL, a bias scan line GBL, an emission control line EL, and a data line DL.

The sub-pixel SPX according to one or more embodiments may include a driving transistor DT, switching elements, a capacitor, and a light emitting element LE. The switching elements include first to sixth transistors ST1, ST2, ST3, ST4, ST5, and ST6.

The driving transistor DT may include a gate electrode, a first electrode, and a second electrode. The driving transistor DT controls a drain-source current (Ids, hereinafter referred to as “driving current”) flowing between the first electrode and the second electrode according to a data voltage applied to the gate electrode of the driving transistor DT.

The light emitting element LE may be a micro light emitting diode.

The light emitting element LE emits light according to the driving current Ids. The amount of light emitted from the light emitting element LE may be proportional to the driving current Ids. The anode electrode of the light emitting element LE may be electrically connected to the first electrode of the fourth transistor ST4 and the second electrode of the sixth transistor ST6, and the cathode electrode may be electrically connected to a second power supply line VSL to which a second power supply voltage is applied.

A capacitor C1 may be formed between the gate electrode of a driving transistor DT and a first power supply line VDL to which a first power supply voltage is applied. The first power supply voltage may be a voltage of a higher level than the second power supply voltage. An electrode of the capacitor C1 may be electrically connected to the gate electrode of the driving transistor DT, and another electrode may be electrically connected to the first power supply line VDL.

As shown in FIG. 4, the first to sixth transistors ST1, ST2, ST3, ST4, ST5, and ST6 and the driving transistor DT may all be formed as p-type MOSFET. For example, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, the gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5, and ST6 may be formed as p-type MOSFET and they may be turned on in case that a scan signal of a gate low voltage and an emission control signal are applied to the initialization scan line GIL, the write scan line GWL, the bias scan line GBL, and the emission control line EL, respectively. An electrode of the third transistor ST3 may be connected to a first initialization voltage line VIL to which the third power supply voltage (VINT of FIG. 3) is applied, and an electrode of the fourth transistor ST4 may be connected to a second initialization voltage line VAIL to which the fourth power supply voltage (VAINT of FIG. 3) is applied. The third power supply voltage (VINT of FIG. 3) and the fourth power supply voltage (VAINT of FIG. 3) may be different voltages. Further, the third power supply voltage (VINT in FIG. 3) and the fourth power supply voltage (VAINT in FIG. 3) may be voltages at a lower level than the first power supply voltage VDD and at a higher level than the second power supply voltage VSS.

In one or more embodiments, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. For example, the active layers of each of the driving transistor DT, the second transistor ST2, the fourth transistor ST4, the fifth transistor ST5, and the sixth transistor ST6 formed of p-type MOSFETs may be formed of polysilicon, the active layers of each of the first transistor ST1 and the third transistor ST3 formed of an n-type MOSFET may be formed of an oxide semiconductor. Furthermore, because the first transistor ST1 and the third transistor ST3 may be formed as n-type MOSFET, the first transistor ST1 may be turned on in case that a scan signal of the gate high voltage is applied, and the third transistor ST3 may be turned on when an initialization scan signal of the gate high voltage is applied. In contrast, the second transistor ST2, the fourth transistor ST4, the fifth transistor ST5, and the sixth transistor ST6 may be formed as p-type MOSFET so that they may be turned on in case that a scan signal of the gate low voltage and a light emission control signal of a gate low voltage are applied.

In one or more embodiments, the fourth transistor ST4 may be formed as an n-type MOSFET, and the remaining transistors DT, ST1, ST2, ST3, ST5, and ST6 may be formed as p-type MOSFET, in which case the active layer of the fourth transistor ST4 may be formed as an oxide semiconductor, and the active layers of each of the remaining transistors DT, ST1, ST2, ST3, ST5, and ST6 may be formed as polysilicon. Further, the fourth transistor ST4 may be turned on in case that a scan signal of a gate high voltage is applied, whereas the remaining transistors DT, ST1, ST2, ST3, ST5, and ST6 may be turned on in case that a scan signal of a gate low voltage and a light emission control signal are applied.

In one or more embodiments, the first to sixth transistors ST1, ST2, ST3, ST4, ST5, and ST6 and the driving transistor DT may all be formed as n-type MOSFET. For example, the active layer of each of the first to sixth transistors ST1, ST2, ST3, ST4, ST5, and ST6 and the driving transistor DT may be formed of an oxide semiconductor and may be turned on in case that a scan signal of a gate high voltage and a light emission control signal are applied.

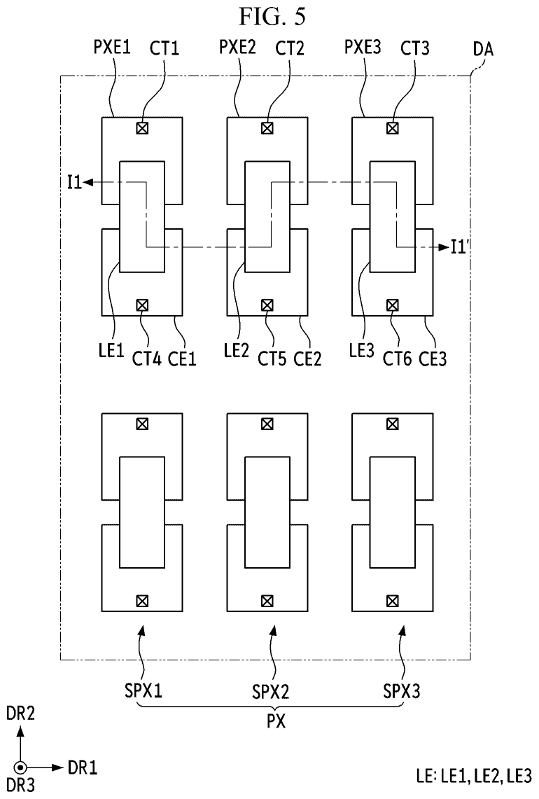

FIG. 5 is a layout diagram illustrating pixels of a display area according to one or more embodiments.

Referring to FIG. 5, each of the plurality of pixels PX of the display area DA may include three sub-pixels SPX1, SPX2, and SPX3, but the present disclosure is not limited thereto and may include four sub-pixels. When each of the plurality of pixels PX includes three sub-pixels, the three sub-pixels may be the first sub-pixel SPX1, the second sub-pixel SPX2, and the third sub-pixel SPX3.

The plurality of pixels PX may be arranged in a matrix form. In each of the plurality of pixels PX, the first sub-pixel SPX1, the second sub-pixel SPX2, and the third sub-pixel SPX3 may be arranged along a first direction DR1.

When each of the plurality of pixels PX includes three sub-pixels SPX1, SPX2, and SPX3, the first sub-pixel SPX1 may emit light of a first color, the second sub-pixel SPX2 may emit light of a second color, and the third sub-pixel SPX3 may emit light of a third color. To this end, the first light emitting element LE1 may emit light of a first color, the second light emitting element LE2 may emit light of a second color, and the third light emitting element LE3 may emit light of a third color. Here, the light of the first color may be light in a red wavelength band, the light of the second color may be light in a green wavelength band, and the light of the third color may be light in a blue wavelength band. For example, the blue wavelength band may refer to the light having a main peak wavelength in a wavelength band from approximately 370 μm to 460 μm, the green wavelength band may refer to the light having a main peak wavelength in a wavelength band from approximately 480 μm to 560 μm, and the red wavelength band may refer to the light having a main peak wavelength in a wavelength band from approximately 600 μm to 750 μm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1, a first light emitting element LE1, and a first common electrode CE1. The second sub-pixel SPX2 includes a second pixel electrode PXE2, second light emitting elements LE2, and a second common electrode CE2. The third sub-pixel SPX3 includes a third pixel electrode PXE3, a third light emitting element LE3, and a third common electrode CE3.

In each of the first sub-pixel SPX1, the second sub-pixel SPX2, and the third sub-pixel SPX3, the pixel electrodes PXE1, PXE2, and PXE3 and the common electrodes CE1, CE2, and CE3 may be arranged along the second direction DR2. Each of the pixel electrodes PXE1, PXE2, and PXE3 and the common electrodes CE1, CE2, and CE3 may have a rectangular plane shape, but the present disclosure is not limited thereto.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the first electrode of the fourth transistor (ST4 in FIG. 4) and the second electrode of the sixth transistor (ST6 in FIG. 4) of the corresponding sub-pixel.

The first common electrode CE1 may be connected to a second power supply line VSL to which a second driving voltage VSS is applied through a first common connection hole CT4. The second common electrode CE2 may be connected to a second power supply line VSL through a second common connection hole CT5. The third common electrode CE3 may be connected to the second power supply line VSL through a third common connection hole CT6. Therefore, the second driving voltage VSS may be applied to each of the common electrodes CE1, CE2, and CE3. The pixel electrodes PXE1, PXE2, and PXE3 may be referred to as an anode electrode or a first electrode, and the common electrodes CE1, CE2, and CE3 may be referred to as a cathode electrode or a second electrode.

A plurality of light emitting elements LE may be arranged on the pixel electrodes PXE1, PXE2, and PXE3 and the common electrode CE1, CE2, and CE3. Each of the plurality of light emitting elements LE may have a rectangular planar shape, but the present disclosure is not limited thereto. For example, each of the plurality of light emitting elements LE may have a circular planar shape.

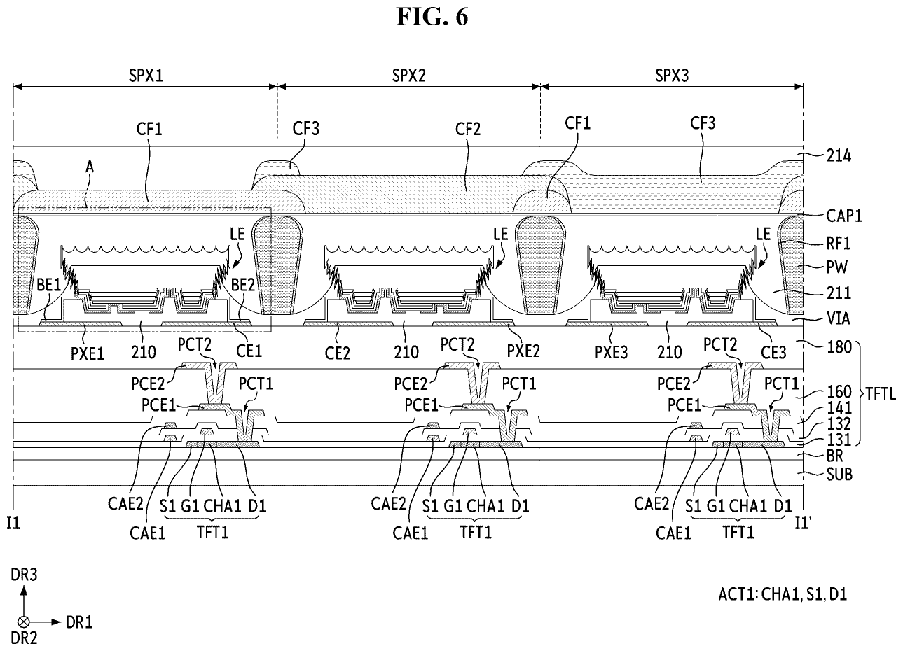

FIG. 6 is a cross-sectional view illustrating an example cross-section of one display panel corresponding to the lines I1-I1′ in FIG. 5.

Referring to FIG. 6, a substrate SUB may be made of an insulating material such as glass, polymer resin, or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be arranged on the substrate SUB. The barrier film BR is a film for protecting the thin-film transistors TFT1 of the thin-film transistor layer TFTL from moisture penetrating through the substrate SUB which is vulnerable to moisture permeation. The barrier film BR may be formed of a plurality of inorganic films that are alternately stacked.

A thin-film transistor TFT1 may be arranged on the barrier film BR. The thin-film transistor TFT1 may be either the fourth transistor ST4 or the sixth transistor ST6 shown in FIG. 4. The thin-film transistor TFT1 may include a first active layer ACT1 and a first gate electrode G1.

The first active layer ACT1 of the thin-film transistor TFT1 may be arranged on the barrier film BR. The first active layer ACT1 of the thin-film transistor TFT1 may include polycrystalline silicon, monocrystalline silicon, low-temperature polycrystalline silicon, and/or amorphous silicon. Alternatively, the first active layer ACT1 of the thin-film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be arranged on one side of the first channel area CHA1, and the first drain area D1 may be arranged on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be arranged on the first channel area CHA1, the first source area S1, and the first drain area D1 of the thin-film transistor TFT1 and on the barrier film BR.

A first gate metal layer may be arranged on the first gate insulating film 131. The first gate metal layer may include a first gate electrode G1 of a thin-film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being arranged apart (e.g., spaced apart) from each other in FIG. 6, the first gate electrode G1 and the first capacitor electrode CAE1 may be connected to each other.

A second gate insulating film 132 may be arranged on the first gate electrode G1 of the thin-film transistor TFT1, the first capacitor electrode CAE1, and on the first gate insulating film 131.

A second gate metal layer may be arranged on the second gate insulating film 132. The second gate metal layer may include a second capacitor electrode CAE2. The second capacitor electrode CAE2 may overlap the first capacitor electrode CAE1 of the thin-film transistor TFT1 in the third direction DR3. Because the second gate insulating film 132 has a suitable dielectric constant (e.g., a predetermined dielectric constant), the capacitor (C1 in FIG. 4) may be formed by the first capacitor electrode CAE1, the second capacitor electrode CAE2, and the second gate insulating film 132 arranged between them.

A first interlayer insulating film 141 may be arranged on the second capacitor electrode CAE2 and on the second gate insulating film 132.

A first data metal layer may be arranged on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the first interlayer insulating film 141.

A first planarization organic film 160 may be arranged on the first source connection electrode PCE1 to planarize a step caused by the thin-film transistor TFT1 and may also be disposed on the first interlayer insulating film 141.

A second data metal layer may be arranged on the first planarization organic film 160. The second data metal layer may include a second source connection electrode PCE2. The second source connection electrode PCE2 may be connected to the first source connection electrode PCE1 through a second pixel contact hole PCT2 penetrating the first planarization organic film 160.

A second planarization organic film 180 may be arranged on the second source connection electrode PCE2 and on the first planarization organic film 160.

The barrier film BR, the first gate insulating film 131, the second gate insulating film 132, and the first interlayer insulating film 141 may be formed of an inorganic film, such as silicon nitride (SiNₓ), silicon oxide nitride (SiON), silicon oxide (SiOₓ), titanium oxide (TiOₓ), and/or aluminum oxide (AlOₓ).

The first gate metal layer, the second gate metal layer, the first data metal layer, and the second data metal layer may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof.

The first planarization organic film 160 and the second planarization organic film 180 may be formed of an organic film such as an acrylic resin, an epoxy resin, a phenolic resin, a polyamide resin, a polyimide resin, and/or the like.

A light emitting element layer may be arranged on the second planarization organic film 180. The light emitting element layer may include pixel electrodes PXE1, PXE2, and PXE3, light emitting elements LE, common electrodes CE1, CE2, and CE3, a first organic layer 210, connection electrodes BE1 and BE2, a partition wall PW, a reflective layer RF1, and a via layer VIA. Further, in one or more embodiments, the light emitting element layer may further include a wavelength conversion layer. The wavelength conversion layer may convert or shift a peak wavelength of incident light into light of another specific peak wavelength and emit the light.

The pixel electrode layer including pixel electrodes PXE1, PXE2, and PXE3 and common electrodes CE1, CE2, and CE3 may be arranged on the second planarization organic film 180.

Each of the first pixel electrode PXE1, the second pixel electrode PXE2, and the third pixel electrode PXE3 may be connected to a second source connection electrode PCE2 through a connection hole (CT1/CT2/CT3 in FIG. 5) penetrating the second planarization organic film 180. Each of the pixel electrodes PXE1, PXE2, and PXE3 may be connected to a first source area S1 or a first drain area D1 of a thin film transistor TFT1 through the first source connection electrode PCE1 and the second source connection electrode PCE2. Therefore, a voltage controlled by the thin film transistor TFT1 may be applied to each of the pixel electrodes PXE1, PXE2, and PXE3.

The common electrodes CE1, CE2, and CE3 may be connected to a second power line (VSL in FIG. 4) to which a second driving voltage (VSS in FIG. 3) is applied through a common connection hole (CT4/CT5/CT6 in FIG. 5). The first common electrode CE1 may be connected to the second power supply line VSL through the first common connection hole CT4. The second common electrode CE2 may be connected to the second power supply line VSL through the second common connection hole CT5. The third common electrode CE3 may be connected to the second power supply line VSL through the third common connection hole CT6. Therefore, the second driving voltage VSS may be applied to each of the common electrodes CE1, CE2, and CE3.

The pixel electrode layer may be formed as a single layer or multiple layers of molybdenum (Mo), aluminum (Al), chromium (Cr), gold (Au), titanium (Ti), nickel (Ni), neodymium (Nd), and/or copper (Cu), and/or alloys thereof. For example, the pixel electrode layer may be made of copper (Cu) having low surface resistance to lower the resistance of each of the pixel electrodes PXE1, PXE2, and PXE3.

The first organic layer 210 may be arranged on each of the pixel electrode layers. For example, the first organic layer 210 may cover at least a portion of the pixel electrodes PXE1, PXE2, and PXE3 and at least a portion of the common electrodes CE1, CE2, and CE3.

The first organic layer 210 temporarily fixes or adheres an upper member (e.g., a light emitting element LE). For example, the first organic layer 210 may be a film for pseudo-adhesion an upper member (e.g., a light emitting element LE) onto each of the pixel electrodes PXE1, PXE2, and PXE3 and the common electrodes CE1, CE2, CE3. To facilitate the pseudo-adhesion, the thickness of the first organic layer 210 may be greater than the thickness of each of the pixel electrodes PXE1, PXE2, and PXE3 and the common electrodes CE1, CE2, and CE3 and may be greater than the thickness of the contact electrode CTE (e.g., CTE1, CTE2). The thickness of the first organic layer 210 may be about 2 μm but is not limited thereto.

The first organic layer 210 may be a photosensitive organic film such as a photoresist. Alternatively, the first organic layer 210 may be formed from an acrylic resin, an epoxy resin, a phenolic resin, a polyamide resin, a polyimide resin, and/or the like.

The plurality of light emitting elements LE may be arranged on the first organic layer 210. In FIG. 6, the light emitting element LE is illustrated as a flip-type micro LED. The flip-type micro LED refers to an LED in which contact electrodes CTE1 and CTE2 are formed on one surface (e.g., the bottom surface) of the light emitting element LE.

The light emitting element LE may have various shapes, such as a shape of a rod, wire, tube, etc., a shape of a polygonal column such as a regular hexahedron, a rectangular parallelepiped, a hexagonal column, etc., or a shape that extends in one direction but has a partially sloped outer surface.

Each of the plurality of light emitting elements LE may be formed from an inorganic material such as gallium nitride (GaN).

Each of the plurality of light emitting elements LE may be formed by growing on a semiconductor substrate such as a silicon substrate or a sapphire substrate. The plurality of light emitting elements LE may be transferred onto the pixel electrode layer of the display panel 100 directly from the semiconductor substrate or through a relay substrate. Alternatively, the plurality of light emitting elements LE may be transferred onto the pixel electrodes PXE1, PXE2, and PXE3 of the display panel 100 by an electrostatic method using an electrostatic head or a stamp method using an elastic polymer material such as PDMS (Polydimethylsiloane) or silicon as a transfer substrate.

The length in the first direction DR1 or the length in the second direction DR2 of the light emitting element LE may be approximately 7 μm to 10 μm but is not limited thereto. Furthermore, the length in the third direction DR3 of the light emitting element LE may be approximately 1 μm to 5 μm. However, the length in the third direction DR3 of the light emitting element LE may be equal to or smaller than the length in the horizontal direction.

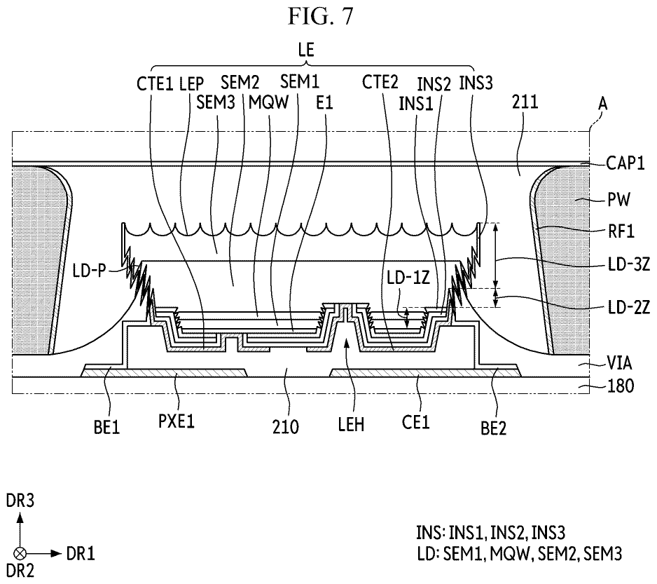

The light emitting element LE will be described in detail with reference to FIGS. 7 and 8.

The connection electrodes BE1 and BE2 electrically connect the light emitting element LE and the pixel electrode layer.

In one or more embodiments, the first connection electrode BE1 electrically connects the first contact electrode CTE1 of the light emitting element LE and the pixel electrodes PXE1, PXE2, and PXE3.

The first connection electrode BE1 is arranged along the side of the light emitting element LE and may be arranged on the first contact electrode CTE1 of the light emitting element LE, and may be arranged on the pixel electrode PXE1, PXE2, and PXE3 that is not covered by the first organic layer 210.

The second connection electrode BE2 electrically connects the second contact electrode CTE2 of the light emitting element LE and the common electrode CE1, CE2, and CE3.

The second connection electrode BE2 is arranged along the side of the light emitting element LE and may be arranged on the common electrode CE1, CE2, and CE3 that is not covered by the first organic layer 210.

In the third direction DR3, the spacing distance between the first connection electrode BE1 and the second connection electrode BE2 and the top surface of the light emitting element LE may be greater than the spacing distance between the first contact electrode CTE1 and the second contact electrode CTE2 and the top surface of the light emitting element LE, but the present disclosure is not limited thereto. For example, in the third direction DR3, the spacing distance between the first connection electrode BE1 and the second connection electrode BE2 and the top surface of the light emitting element LE may be substantially equal to the spacing distance between the first contact electrode CTE1 and the second contact electrode CTE2 and the top surface of the light emitting element LE.

The first connection electrode BE1 and the second connection electrode BE2 may include a transparent conductive oxide, such as indium tin oxide (ITO) and/or indium zinc oxide (IZO), or a metal, such as copper (Cu), titanium (Ti), aluminum (Al), molybdenum (Mo), tantalum (Ta), calcium (Ca), chromium (Cr), magnesium (Mg), and/or nickel (Ni).

A via layer VIA may cover a portion of a side surface of the light emitting element LE. The height of the via layer VIA may be higher than the height of the contact electrodes CTE1 and CTE2. That is, the via layer VIA may be arranged to cover the contact electrodes CTE1 and CTE2 arranged on the side surface of the light emitting element LE.

The via layer VIA may be formed of an organic film such as an acrylic resin, an epoxy resin, a phenolic resin, a polyamide resin, a polyimide resin, and/or the like.

A partition wall PW that divides each light emitting area may be arranged on the via layer VIA.

The partition wall PW may define each light emitting area. The partition wall PW is arranged to extend in the first direction DR1 and the second direction DR2 and may be formed in a grid-shaped pattern throughout the display area DA. Further, the partition wall PW does not overlap with a plurality of light emitting areas and may overlap with a non-light emitting area.

The partition wall PW may include an organic insulating material. The organic insulating material may include, for example, an epoxy-based resin, an acrylic-based resin, a cardo-based resin, and/or an imide-based resin.

In one or more embodiments, the partition wall PW may include a light-blocking material to prevent light from a light emitting element LE of a sub-pixel from traveling to an adjacent sub-pixel. For example, the partition wall PW may include an inorganic black pigment such as carbon black or an organic black pigment. Accordingly, the partition wall PW may also be referred to as a light blocking layer.

In one or more embodiments, the partition wall PW is formed as a single layer, but is not limited thereto, and the partition wall PW may be formed as a double layer. The height of the partition wall PW may be higher than the height of the light emitting element LE. The height of the partition wall PW may be about 8 μm to 14 μm. The height of the partition wall PW may mean a length from the top of the second planarization organic film 180 in the third direction DR3.

In one or more embodiments, the partition wall PW may be formed by a negative photo resist and may have a reverse tapered shape but is not limited thereto.

A reflective layer RF1 may be arranged on the inner wall of the partition wall PW. The reflective layer RF1 may include a metal material having a high reflectivity, such as aluminum (Al). For example, the reflective layer RF1 may include aluminum and/or silver and may also include an alloy thereof. The thickness of the reflective layer RF1 may be approximately 0.1 μm.

Alternatively, the reflective layer RF1 may include M pairs of first and second layers having different refractive indices (M is an integer greater than or equal to 2) to serve as distributed Bragg reflectors (DBR). In this case, the M first layers and the M second layers may be alternately arranged. The first layer and the second layer may be formed of an inorganic film, such as silicon nitride (SiNₓ), silicon oxide nitride (SiON), silicon oxide (SiOₓ), titanium oxide (TiOₓ), and/or aluminum oxide (AlOₓ).

A second organic layer 211 covering the light emitting element LE may be filled inside the space formed by the partition wall PW. The second organic layer 211 may include a light-transmission organic material. The second organic layer 211 may include an epoxy-based resin, an acrylic-based resin, a cardo-based resin, and/or an imide-based resin.

A first capping layer CAP1 may be arranged on the partition wall PW and the second organic layer 211. The first capping layer CAP1 may include an inorganic material. For example, the first capping layer CAP1 may include silicon nitride, aluminum nitride, zirconium nitride, titanium nitride, hafnium nitride, tantalum nitride, silicon oxide, aluminum oxide, titanium oxide, tin oxide, cerium oxide, and/or silicon oxynitride.

A plurality of color filters CF1, CF2, and CF3 may be arranged on the first capping layer CAP1. The plurality of color filters CF1, CF2, and CF3 may include first color filters CF1, second color filters CF2, and third color filters CF3.

The first color filter CF1 arranged on the first sub-pixel SPX1 may transmit first light (e.g., light in a red wavelength band) and absorb or block the second light and the third light (e.g., light in the green and blue wavelength bands). Accordingly, the first sub-pixel SPX1 may emit the first light (e.g., light in the red wavelength band).

The second color filter CF2 arranged in the second sub-pixel SPX2 may transmit the second light (e.g., light in the green wavelength band) and absorb or block the first light and the third light (e.g., light in the red and blue wavelength bands). Accordingly, the second sub-pixel SPX2 may emit the second light (e.g., light in the green wavelength band).

The third color filter CF3 arranged in the third sub-pixel SPX3 may transmit the third light (e.g., light in the blue wavelength band). Accordingly, the third sub-pixel SPX3 may emit the third light (e.g., light in the blue wavelength band).

The first color filter CF1, the second color filter CF2, and the third color filter CF3 overlapping in the third direction DR3 may overlap the partition wall PW in the third direction DR3.

A fifth organic film 214 for planarization may be arranged on the plurality of color filters CF1, CF2, and CF3.

The fifth organic film 214 may be formed from an acrylic resin, an epoxy resin, a phenolic resin, a polyamide resin, a polyimide resin, and/or the like.

In one or more embodiments, the first light emitting element LE1, the second light emitting element LE2, and the third light emitting element LE3 may emit light of the same color. In this case, at least one of a light conversion layer (e.g., a light conversion layer including wavelength conversion particles such as quantum dots) and a color filter may be arranged to convert light emitted from the light emitting element LE of the corresponding sub-pixel SPX into light corresponding to the light emission color of the corresponding sub-pixel SPX on at least one light emitting element LE among the first sub-pixel SPX1, the second sub-pixel SPX2, and the third sub-pixel SPX3. When the first light emitting element LE1, the second light emitting element LE2, and the third light emitting element LE3 emit light of the same color, the sizes of the first light emitting element LE1, the second light emitting element LE2, and the third light emitting element LE3 may be the same or different.

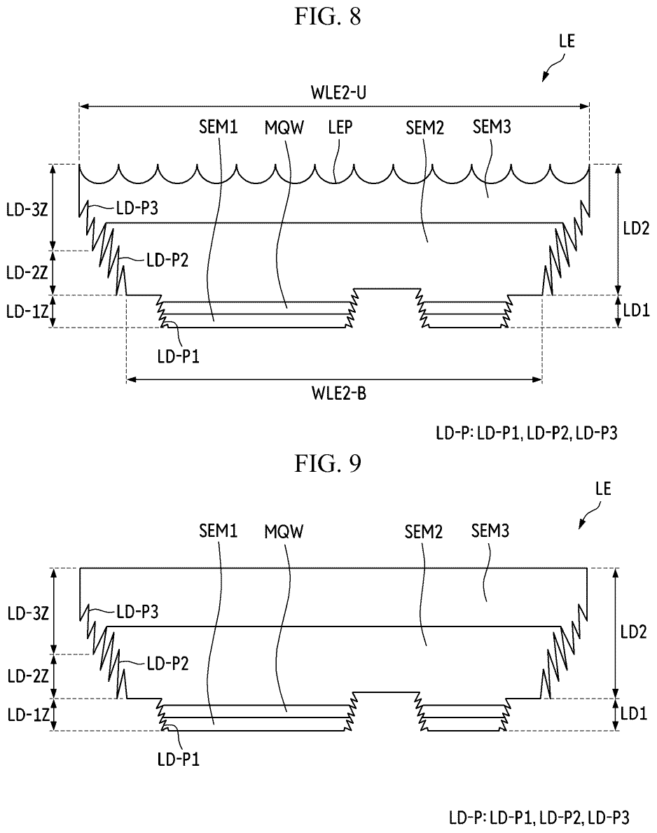

FIG. 7 is a cross-sectional view illustrating an example of an area A in FIG. 6 in detail. FIG. 8 is an enlarged cross-sectional view of a semiconductor layer of the light emitting element of FIG. 7. FIG. 9 is an enlarged cross-sectional view of the semiconductor layer of the light emitting element of FIG. 7 according to another embodiment.

Referring to FIGS. 7 and 8, each of the plurality of light emitting elements LE may include a conductive layer E1, a first semiconductor layer SEM1, an active layer MQW, a second semiconductor layer SEM2, a third semiconductor layer SEM3, protective films INS1, INS2, and INS3, a first contact electrode CTE1, and a second contact electrode CTE2.

The conductive layer E1 may be arranged on the bottom surface of the first semiconductor layer SEM1. In FIG. 7, the conductive layer E1 is illustrated as covering the entire bottom surface of the first semiconductor layer SEM1, but the present disclosure is not limited thereto. For example, the conductive layer E1 may be arranged on a portion of the bottom surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu).

The first semiconductor layer SEM1 may be arranged on the conductive layer E1. The first semiconductor layer SEM1 may be formed of a semiconductor material layer doped with a first conductive dopant such as magnesium (Mg), zinc (Zn), calcium (Ca), strontium (Sr), barium (Ba), etc., for example, gallium nitride (GaN).

The active layer MQW may be arranged on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) or aluminum gallium nitride (AlGaN), but the present disclosure is not limited thereto.

Alternatively, the active layer MQW may have a structure in which semiconductor materials having a high band gap energy and semiconductor materials having a low band gap energy are alternately stacked with each other, may include other Group III to Group V semiconductor materials according to the wavelength range of emitted light.

In one or more embodiments, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (e.g., light in the blue wavelength band) may be approximately 10 wt % to 20 wt %.

The second semiconductor layer SEM2 may be arranged on the active layer MQW. The second semiconductor layer SEM2 may be a semiconductor material layer doped with a second conductivity type dopant such as silicon (Si), germanium (Ge), tin (Sn), etc., for example, gallium nitride (GaN).

An electron blocking layer may be arranged between the first semiconductor layer SEM1 and the active layer MQW. The electron blocking layer may be a layer to suppress or prevent too many electrons from flowing into the active layer MQW. For example, the electron blocking layer may be aluminum gallium nitride (AlGaN) or p-type aluminum gallium nitride (AlGaN) doped with p-type magnesium (Mg). The electronic blocking layer may be omitted.

A superlattice layer may be arranged between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

The third semiconductor layer SEM3 may be arranged on the second semiconductor layer SEM2.

The third semiconductor layer SEM3 may be a semiconductor material layer having an n-type dopant lower than a suitable threshold value (e.g., a predetermined threshold value) and may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride (InN), where the n-type dopant is below a suitable threshold value (e.g., a predetermined threshold value).

A light extraction pattern LEP may be formed on the top surface of the third semiconductor layer SEM3.

The light extraction patterns LEP may be patterns for increasing the efficiency of light emitted to the top surface of the light emitting element LE. The light extraction patterns LEP may be concave patterns formed in the shape of a hemisphere or a semi-ellipse. The light extraction patterns LEP may be concave patterns having a cross-sectional shape of a semicircle or a semi-ellipse.

As shown in FIG. 9, in one or more embodiments, the top surface of the light emitting element LE may be flat. Furthermore, in one or more embodiments, the third semiconductor layer SEM3 may be omitted.

Referring again to FIG. 8, the first semiconductor layer SEM1, the active layer MQW, the second semiconductor layer SEM2, and the third semiconductor layer SEM3 of the light emitting element LE may be referred to as an element rod LD.

The element rod LD may include a first element rod LD1 and a second element rod LD2 that are distinguished according to the inclination of the side surface. The second element rod LD2 is arranged on the first element rod LD1.

The side surface of the first element rod LD1 may have a greater inclination than the side surface of the second element rod LD2. Thus, the inclination of the side surface of the first element rod LD1 may be steeper than the inclination of the side surface of the second element rod LD2. For example, the side surface of the first element rod LD1 may have a nearly vertical inclination. Accordingly, one side and the other side of the first element rod LD1 may have nearly similar widths, while one side and the other side of the second element rod LD2 may have different widths. For example, the width WLD2-U of the other side (upper surface) of the second element rod LD2 may be wider than the width WLD2-B of one side (lower surface) of the second element rod LD2.

The first element rod LD1 may include a conductive layer E1, a first semiconductor layer SEM1, and an active layer MQW. The first element rod LD1 may have a height in the range of 0.3 μm to 0.5 μm but is not limited thereto.

The sides of the first element rod LD1 and the second element rod LD2 may not correspond to each other and may have a step but is not limited thereto. The sides of the first element rod LD1 and the second element rod LD2 may not match each other and may have a step but are not limited thereto.

The second element rod LD2 may include a second semiconductor layer SEM2 and a third semiconductor layer SEM3.

Referring to FIG. 7, the protective film INS may be a film for protecting the bottom surface and the side surface of the light emitting element LE. The protective film INS may include a first protective film INS1, a second protective film INS2, and a third protective film INS3. The first protective film INS1 and the second protective film INS2 are arranged on one surface of the first element rod LD1 and the side surface of the first element rod LD1, and the second protective film INS2 may be around (e.g., may surround) the first protective film INS1 and may be on the side surfaces and a bottom surface of the light emitting element LE.

In one or more embodiments, the first protective film INS1 and the second protective film INS2 may be arranged on the bottom surface and side surface of the conductive layer E1 and on some of the side surface of the semiconductor layers SEM1, MQW, and SEM2. Specifically, the protective film INS may be arranged on the bottom surface and side surface of the conductive layer E1, the side surface of the first semiconductor layer SEM1, the side surface of the active layer MQW, and a portion of the side surface of the second semiconductor layer SEM2. The third protective film INS3 may be arranged on one surface (bottom surface) and side surface of the light emitting element LE excluding the upper surface of the light emitting element LE. The bottom surface of the light emitting element LE may be a surface facing the top surface of the light emitting element LE.

The protective film INS may be formed of an inorganic film, such as silicon nitride (SiNₓ), silicon oxide nitride (SiON), silicon oxide (SiOₓ), titanium oxide (TiOₓ), and/or aluminum oxide (AlOₓ). The protective film INS is located (e.g., preferably arranged) from one end to the other end of the side of the light emitting element LE but may be spaced (e.g., spaced apart) from one end due to process errors.

A hole LEH may be formed to expose the second semiconductor layer SEM2 by penetrating the conductive layer E1, the first semiconductor layer SEM1, and the active layer MQW of the light emitting element LE. The hole LEH may have a rectangular planar shape, but the present disclosure is not limited thereto. For example, the hole LEH may have a polygonal planar shape such as a circle, an ellipse, or a square.

In addition, the protective film INS may be arranged on the sidewall of the conductive layer E1, the sidewall of the first semiconductor layer SEM1, and the sidewall of the active layer MQW exposed in the hole LEH. The protective film INS may not cover the second semiconductor layer SEM2 in the hole LEH. Therefore, the second semiconductor layer SEM2 exposed by the hole LEH may be exposed without being covered by the protective film INS.

The first contact electrode CTE1 may be arranged on at least one side surface and the bottom surface of the first element rod LD1. The first contact electrode CTE1 may be arranged on the bottom surface of the conductive layer E1 exposed without being covered by the protective film INS and may extend to the side surface of the first element rod LD1. The first contact electrode CTE1 may be electrically connected to the conductive layer E1.

The second contact electrode CTE2 may be arranged on at least one side surface and the bottom surface of the first element rod LD1. At this time, the first contact electrode CTE1 may be arranged on the first side of the first element rod LD1 and the first side of the conductive layer E1, while the second contact electrode CTE2 may be arranged on the second side of the first element rod LD1 and the second side of the conductive layer E1.

The second contact electrode CTE2 may be arranged on the protective film INS arranged in the hole LEH and the second semiconductor layer SEM2 exposed in the hole LEH without being covered by the protective film INS. Therefore, the second contact electrode CTE2 may be electrically connected to the second semiconductor layer SEM2 in the hole LEH.

The first contact electrode CTE1 and the second contact electrode CTE2 may be arranged on at least a portion of a side of the first element rod LD1. The side surface of the second element rod LD2 may be exposed without being covered by the first contact electrode CTE1 and the second contact electrode CTE2.

The first contact electrode CTE1 and the second contact electrode CTE2 may include molybdenum (Mo), aluminum (Al), chromium (Cr), gold (Au), titanium (Ti), nickel (Ni), neodymium (Nd), and/or copper (Cu). Specifically, the first contact electrode CTE1 and the second contact electrode CTE2 may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

Each of the first contact electrode CTE1 and the second contact electrode CTE2 may be arranged on three sides of the first element rod LD1. For example, when the first element rod LD1 includes first to fourth sides, the first contact electrode CTE1 may be arranged on the first side, the second side, and the third side, and the second contact electrode CTE2 may be arranged on the second side, the third side, and the fourth side.

The side of the semiconductor layer, that is, the side of the first element rod LD1 and the second element rod LD2, has a roughness pattern. The roughness pattern is formed by an etching process and has a fine protrusion shape. As shown in FIG. 8, each protrusion LD-P has a shape that becomes thinner toward the outside of the light emitting element LE. For example, the cross-section of each protrusion LD-P may have a shape such as a triangular pyramid, a square pyramid, or a cone. Each of these protrusions LD-P induces multiple reflections of light, which contributes to reducing internal reflections and increasing or maximizing the amount of light emitted to the outside, thereby improving the overall light extraction efficiency.

On the other hand, the side of the semiconductor layer may be divided into a plurality of regions in a direction perpendicular to the substrate. For example, a light emitting element LE (e.g., first element rod LD1) may be divided into a first region LD-1Z, a second region LD-2Z, and a third region LD-3Z from one surface to an upper surface. The first region LD-1Z may be a region from one side of the light emitting element LE (the first element rod LD1) to the interface between the active layer MQW and the second semiconductor layer SEM2. The height of the first region LD-1Z in the direction perpendicular to the substrate (e.g., the third direction DR3) may be about 1000 nm.

The second region LD-2Z may be located on top of the first region LD-1Z and may be a region where the contact electrode CTE1 is arranged from the interface between the active layer MQW and the second semiconductor layer SEM2. The height of the second region LD-2Z in the direction perpendicular to the substrate may be about 250 nm.

The third region LD-3Z may be a side region of the light emitting element LE located above the second region LD-2Z and where the contact electrode CTE1 is not arranged. The height in the direction perpendicular to the substrate of the third region LD-3Z may be about 4000 nm or more.

The side surface of the semiconductor layer, that is, the side surface of the first element rod LD1 and the second element rod LD2, may have differently shaped protrusions LD-P in the first region LD-1Z, the second region LD-2Z, and the third region LD-3Z. The sizes and/or shapes of the protrusions of the first region LD-1Z, the second region LD-2Z, and the third region LD-3Z may be different. For example, as shown in FIG. 8, the protrusions LD-P1 of the first region LD-1Z may be smaller than the protrusions of the other regions. The protrusions LD-P3 in the third region LD-3Z may be large compared to the protrusions in the other regions, i.e., the size of the protrusions increases from the first region LD-P1 to the third region LD-3Z. For example, the size of the protrusion LD-P1 of the first region LD-1Z may be 1 μm or less. The size of the protrusion LD-P2 of the second region LD-2Z may be more than 1 μm and less than 3 μm. The size of the protrusion LD-P2 of the third region LD-3Z may be 3 μm or more.

In the case of the first region LD-1Z and the second region LD-2Z where the contact electrodes CTE1 and CTE2 are arranged, the protrusions may be separated on contact with the contact electrodes CTE1 and CTE2 if they are too large. In one or more embodiments, the first region LD-1Z and the second region LD-2Z may be formed as a single region. Even in this case, the integrated first region LD-1Z and second region LD-2Z may have protrusions of a smaller size than the protrusions of the third region LD-3Z.

The protrusions of the third region LD-3Z where the contact electrodes CTE1 and CTE2 are not arranged may be formed larger than those of the other regions to increase light extraction efficiency.

The contact electrodes CTE1 and CTE2 may be at least partially buried in the first organic layer 210. For example, the contact electrodes CTE1 and CTE2 corresponding to the first region LD-1Z of the light emitting element LE may be surrounded by the first organic layer 210.

One side and side surfaces of the contact electrodes CTE1 and CTE2 may be in direct contact with the first organic layer 210.

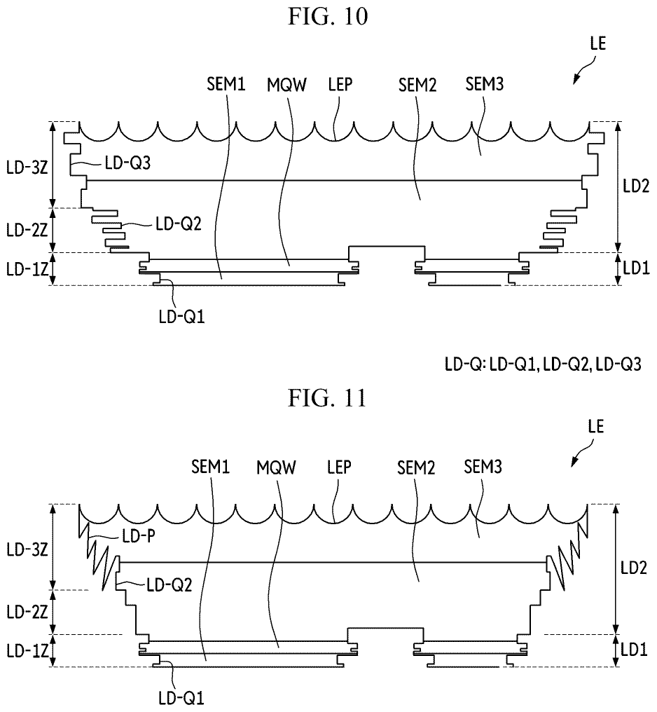

FIG. 10 and FIG. 11 are enlarged cross-sectional views of the semiconductor layer of the light emitting element of FIG. 7 according to one or more embodiments.

FIG. 10 and FIG. 11 are different from the embodiment of FIG. 8 in that the shapes of the protrusions on the side surfaces of the semiconductor layer are different. In FIG. 10 and FIG. 11, the overlapping descriptions with the embodiments described with reference to FIG. 7 and FIG. 8 will not be repeated, and the differences from the embodiment of FIG. 7 will be mainly described.

FIG. 10 illustrates that a plurality of protrusions LD-Q in the first region LD-1Z, the second region LD-2Z, and the third region LD-3Z have an irregular pattern. The irregular pattern means that the width and height of each protrusion LD-Q are randomly distributed. The protrusions LD-Q with such an irregular pattern have the effect of scattering light in various directions.

Even when the plurality of protrusions LD-Q in the first region LD-1Z, the second region LD-2Z, and the third region LD-3Z have irregular patterns, the average size of the plurality of protrusions LD-Q1 in the first region LD-1Z may be smaller than the average size of the plurality of protrusions in the other regions. The average size of the plurality of protrusions LD-Q3 in the third region LD-3Z may be larger than the average size of the plurality of protrusions in the other regions.

As shown in FIG. 11, only the protrusions in some regions may have irregular patterns. For example, the plurality of protrusions LD-Q1 and LD-Q2 in the first region LD-1Z and the second region LD-2Z may have irregular patterns, and in the third region LD-3Z, the shape may taper outward from the light emitting element LE. For example, the cross-section of each protrusion LD-P may have a shape such as a triangular pyramid, a square pyramid, or a cone. In the first region LD-1Z, the average size of the irregular pattern of the plurality of protrusions LD-Q1 may be smaller than the average size of the plurality of protrusions in other regions. The sizes of the plurality of protrusions LP-P in the third region LD-3Z may be larger than the average sizes of the plurality of protrusions in other regions.

In FIG. 11, the plurality of protrusions LD-Q1 and LD-Q2 in the first region LD-1Z and the second region LD-2Z have an irregular pattern, but the present disclosure is not limited thereto. In the first region LD-1Z, the plurality of protrusions LD-Q1 may have an irregular pattern, and in the second region LD-2Z and the third region LD-3Z, the shape may taper outward from the light-emitting element LE. For example, the cross-section of each protrusion LD-P may have a shape such as a triangular pyramid, a square pyramid, or a cone.

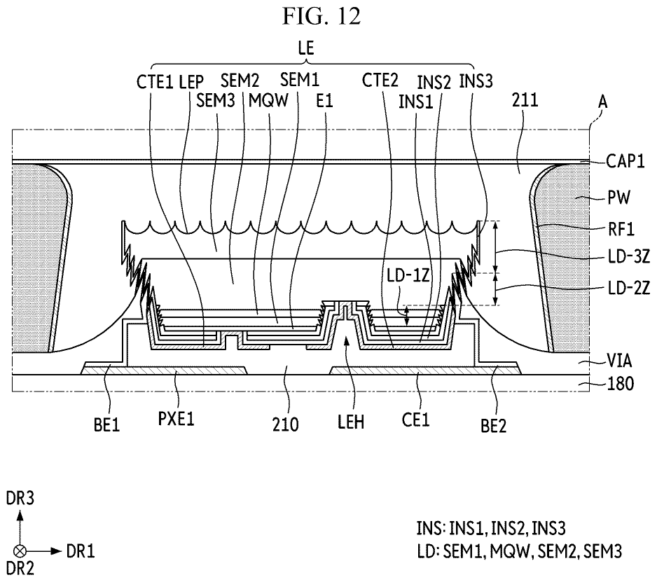

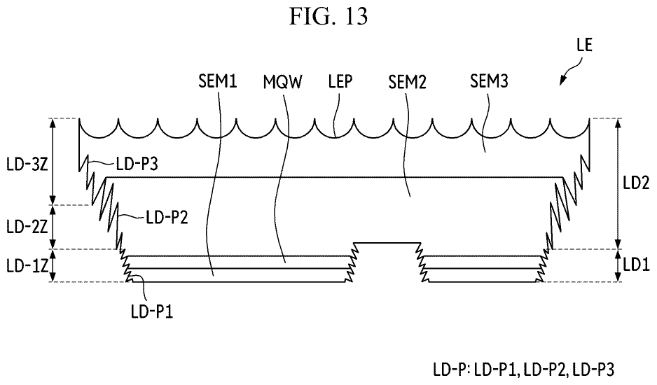

FIG. 12 is a cross-sectional view illustrating in detail an example of the area A area of FIG. 6 according to another embodiment. FIG. 13 is an enlarged cross-sectional view of a semiconductor layer of a light emitting element of FIG. 12.

FIG. 12 and FIG. 13 are different from the light emitting element LE described with reference to FIGS. 7 and 8 in that the side inclination angle of the light emitting element LE is constant.

Even when the side inclination angle of the light emitting element LE is constant, the light emitting element LE may be divided into a first region LD-1Z, a second region LD-2Z, and a third region LD-3Z from one side to the upper direction. The first region LD-1Z may be a region from one side of the light emitting element LE to the interface between the active layer MQW and the second semiconductor layer SEM2. The height of the first region LD-1Z in the direction perpendicular to the substrate may be about 1000 nm.

The second region LD-2Z may be located on top of the first region LD-1Z and may be a region where the contact electrode CTE1 is arranged from the interface between the active layer MQW and the second semiconductor layer SEM2. The height of the second region LD-2Z in the direction perpendicular to the substrate may be about 250 nm.

The third region LD-3Z may be a side region of the light emitting element LE located above the second region LD-2Z and where the contact electrode CTE1 is not arranged. The height in the direction perpendicular to the substrate of the third region LD-3Z may be about 4000 nm or more.

The side of the semiconductor layer may have protrusions LD-P of different shapes in the first region LD-1Z, the second region LD-2Z, and the third region LD-3Z in the direction perpendicular to the substrate. The sizes and/or shapes of the protrusions of the first region LD-1Z, the second region LD-2Z, and the third region LD-3Z may be different. For example, as shown in FIG. 13, the protrusions LD-P1 of the first region LD-1Z may be smaller than the protrusions of the other regions. The protrusions LD-P3 of the third region LD-3Z may be larger than the protrusions of other regions. That is, the size of the protrusions may become larger as one goes from the first region LD-P1 to the third region LD-3Z. For example, the size of the protrusion LD-P1 of the first region LD-1Z may be 1 um or less. The size of the protrusion LD-P2 of the second region LD-2Z may be 1 um to less than 3 um. The size of the protrusion LD-P2 of the third region LD-3Z may be 3 um or more.

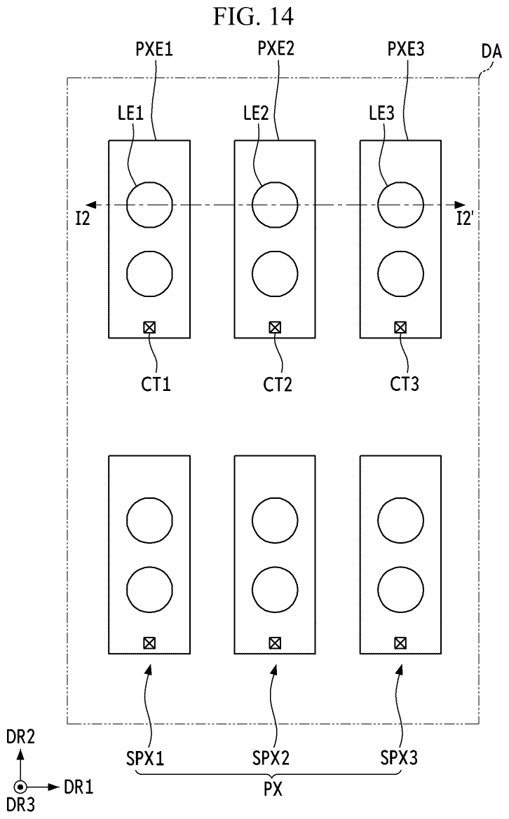

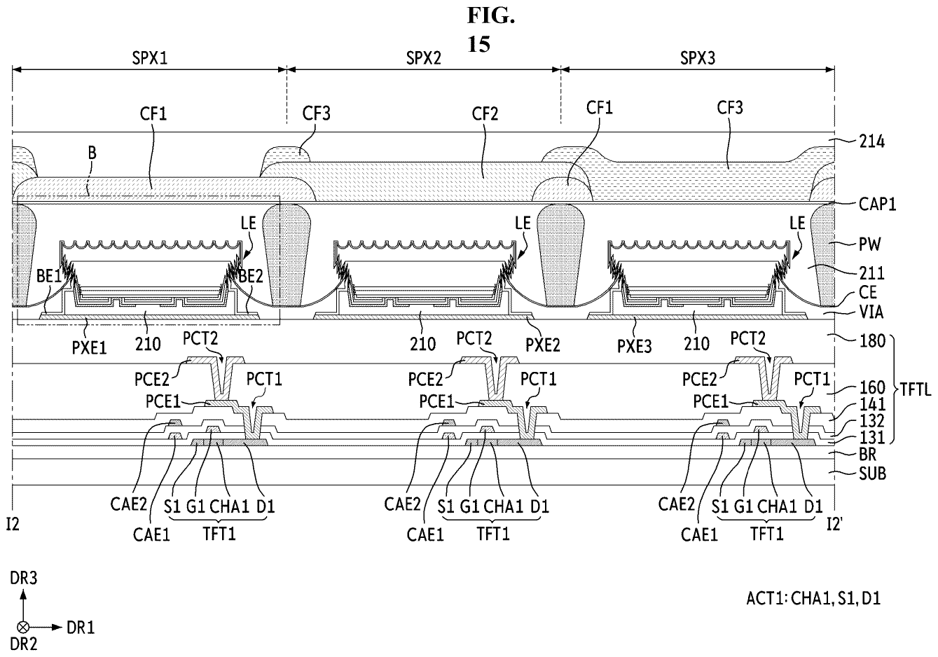

FIG. 14 is a layout diagram illustrating pixels of a display area according to one or more embodiments.

The embodiment of FIG. 14 differs from the embodiment of FIG. 5 in that the light emitting elements LE overlap the pixel electrodes PXE1, PXE2, and PXE3 in each of the first sub-pixel SPX1, the second sub-pixel SPX2, and the third sub-pixel SPX3. In the embodiment of FIG. 14, any description overlapping with the embodiment of FIG. 5 will be omitted.

Referring to FIG. 14, the first sub-pixel SPX1 includes the first pixel electrode PXE1 and the first light emitting elements LE1. The second sub-pixel SPX2 includes the second pixel electrode PXE2 and the second light emitting elements LE2. The third sub-pixel SPX3 includes the third pixel electrode PXE3 and the third light emitting elements LE3. The first light emitting element LE1 may emit light of a first color, the second light emitting element LE2 may emit light of a second color, and the third light emitting element LE3 may emit light of a third color. The light of the first color may be light of a red wavelength band, the light of the second color may be light of a green wavelength band, and the light of the third color may be light of a blue wavelength band. Each of the first pixel electrode PXE1, the second pixel electrode PXE2, and the third pixel electrode PXE3 may have a rectangular planar shape having a short side in the first direction DR1 and a long side in the second direction DR2.

Each of the pixel electrodes PXE1, PXE2, and PXE3 may be electrically connected to at least one transistor through a pixel connection hole CT1, CT2, and CT3. For example, each of the pixel electrodes PXE1, PXE2, and PXE3 may be electrically connected to a first electrode of a fourth transistor (ST4 in FIG. 4) and a second electrode of a sixth transistor (ST6 in FIG. 4) of the corresponding sub-pixel.

A plurality of light emitting elements LE may be arranged on each of the pixel electrodes PXE1, PXE2, and PXE3. The same number of light emitting elements LE may be arranged on each of the pixel electrodes PXE1, PXE2, and PXE3. For example, two light emitting elements LE may be arranged on each of the pixel electrodes PXE1, PXE2, PXE3.

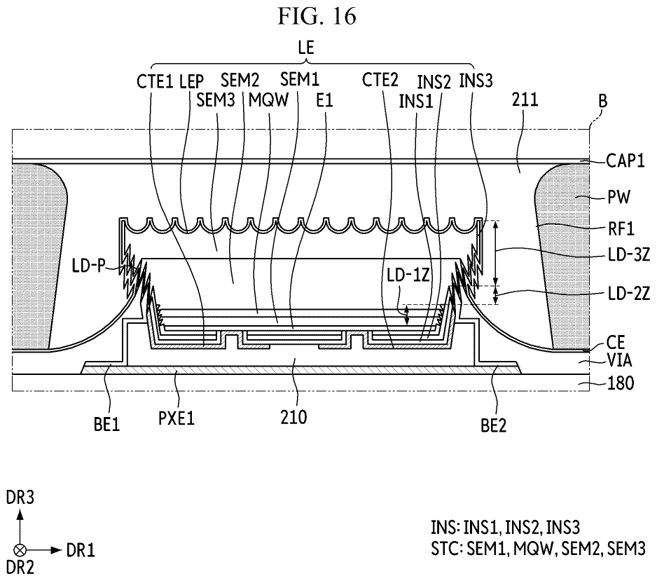

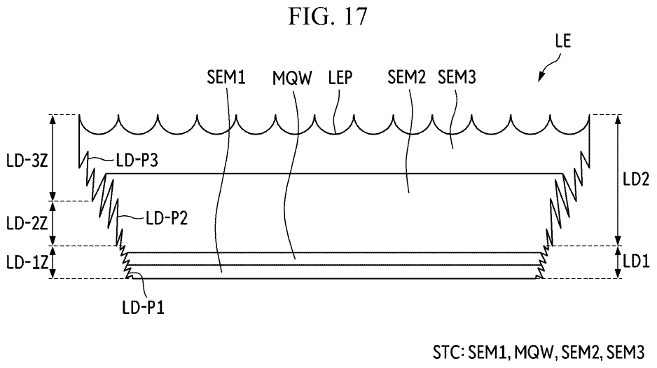

FIG. 15 is a cross-sectional view illustrating an example of a cross-section of a display panel corresponding to the line I2-I2′ of FIG. 14. FIG. 16 is a cross-sectional view illustrating in detail an example of an area B of FIG. 15. FIG. 17 is an enlarged cross-sectional view of a plurality of semiconductor layers of a light emitting element of FIG. 16.

The embodiments of FIGS. 15 and 16 differ from the embodiments of FIGS. 6 and 7 in that the light emitting elements LE are vertical type micro LED in which each of the plurality of light emitting elements LE extends in a third direction DR3. The vertical type micro LED refers to an LED having a structure in which a first semiconductor layer SEM1, an active layer MQW, and a second semiconductor layer SEM2 are sequentially arranged in the third direction DR3, which is a vertical direction. Each of the plurality of light emitting elements LE may include a substantially vertical side surface. The light emitting elements LE may be patterned through vertical etching and may have a rectangular or square cross-sectional shape in which the width of the top surface and the width of the bottom surface are substantially the same.

In the embodiments of FIGS. 15 and 16, any description overlapping with the embodiments of FIGS. 6 and 7 will be omitted.

Referring to FIGS. 15 and 16, a pixel electrode layer may be arranged on the second planarization organic film 180. The pixel electrode layer may include a first pixel electrode PXE1, a second pixel electrode PXE2, and a third pixel electrode PXE3.

The plurality of light emitting elements LE may be arranged on the first organic layer 210.

Each of the plurality of light emitting elements LE may have a length in the first direction DR1, a length in the second direction DR2, and a length in the third direction DR3 of several to several hundred μm, respectively. For example, each of the plurality of light emitting elements LE may have a length in the first direction DR1, a length in the second direction DR2, and a length in the third direction DR3 of approximately 100μm or less, respectively.

The light emitting element LE may include a conductive layer E1, a plurality of semiconductor layers STC, a contact electrode CTE, and a protective film INS. The plurality of semiconductor layers STC may include a first semiconductor layer SEM1, an active layer MQW, a second semiconductor layer SEM2, and a third semiconductor layer SEM3 sequentially arranged in the third direction DR3. A light extraction pattern LEP may be formed on the top surface of the third semiconductor layer SEM3.

A first region LD-1Z, a second region LD-2Z, and a third region LD-3Z may be distinguished from one surface of the light emitting element LE in the upper direction. The first region LD-1Z may be a region from one surface of the light emitting element LE to an interface between the active layer MQW and the second semiconductor layer SEM2. The height of the first region LD-1Z in a direction perpendicular to the substrate may be about 1000 nm.

The second region LD-2Z may be arranged on the upper portion of the first region LD-1Z and may be a region where the contact electrode CTE1 is arranged from the interface between the active layer MQW and the second semiconductor layer SEM2. The height of the second region LD-2Z in the direction perpendicular to the substrate may be about 250 nm.

The third region LD-3Z may be located on the upper portion of the second region LD-2Z and may be a side region of the light emitting element LE where the contact electrode CTE1 is not arranged. The height of the third region LD-3Z in the direction perpendicular to the substrate may be about 4000 nm or more.

The side surfaces of the plurality of semiconductor layers STC may have protrusions LD-P of different shapes in the first region LD-1Z, the second region LD-2Z, and the third region LD-3Z in the direction perpendicular to the substrate. The protrusion sizes and/or shapes of the first region LD-1Z, the second region LD-2Z, and the third region LD-3Z may be different.

For example, as shown in FIG. 17, the protrusions LD-P1 of the first region LD-1Z may be smaller than the protrusions of the other regions. The protrusions LD-P3 of the third region LD-3Z may be larger than the protrusions of other regions. That is, the size of the protrusions may become larger as one goes from the first region LD-P1 to the third region LD-3Z. For example, the size of the protrusion LD-P1 of the first region LD-1Z may be 1 um or less. The size of the protrusion LD-P2 of the second region LD- 2Z may be 1 um to less than 3 um. The size of the protrusion LD-P2 of the third region LD-3Z may be 3 um or more.

The protective film INS may be arranged on the side of the first semiconductor layer SEM1, the side of the active layer MQW, the side of the second semiconductor layer SEM2, and the side of the third semiconductor layer SEM3. The protective film INS may be a film for protecting the side of the light emitting element LE. The protective film INS may be formed of an inorganic film, such as silicon nitride (SiNₓ), silicon oxide nitride (SiON), silicon oxide (SiOₓ), titanium oxide (TiOₓ), and/or aluminum oxide (AlOₓ).

A plurality of contact electrodes CTE may be arranged on the protective film INS. Each of the plurality of contact electrodes CTE may be arranged between the first organic layer 210 and the protective film INS. Each of the plurality of contact electrodes CTE may be in contact with the first organic layer 210.

Each of the plurality of contact electrodes CTE may be connected to a conductive layer E1 that is exposed and not covered by the protective film INS. As a result, even if one of the plurality of contact electrodes CTE is not connected to the conductive layer E1 due to a process error, the occurrence of a defect in which the light emitting element LE does not light up may be prevented by connecting the other contact electrode CTE to the conductive layer E1.

When the plurality of contact electrodes CTE are formed of a metal with high reflectivity, light emitted from the active layer MQW of the light emitting element LE, which travels toward the side of the light emitting element LE, may be reflected by the plurality of contact electrodes CTE and emitted to the top surface of the light emitting element LE. Therefore, because the loss of light from the light emitting element LE may be reduced, the light efficiency of the light emitting element LE may be increased. Therefore, it is desirable (e.g., preferable) that each of the plurality of contact electrodes CTE be arranged to cover most of the side surface of the plurality of semiconductor layers STC to increase the light efficiency of the light emitting element LE.

The plurality of contact electrodes CTE may include molybdenum (Mo), aluminum (Al), chromium (Cr), gold (Au), titanium (Ti), nickel (Ni), neodymium (Nd), and/or copper (Cu). Specifically, the plurality of contact electrodes CTE may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

Each of the plurality of contact electrodes CTE may be arranged on a side surface of the plurality of semiconductor layers STC. Among the side surfaces of the plurality of semiconductor layers STC, an area adjacent to the top surface of the plurality of semiconductor layers STC may be covered by a protective film INS but may be exposed without being covered by the plurality of contact electrodes CTE.

The connection electrodes BE1 and BE2 connect the contact electrode CTE of the light emitting element LE and the pixel electrodes PXE1, PXE2, and PXE3. The connection electrodes BE1 and BE2 are arranged on the pixel electrodes PXE1, PXE2, and PXE3 that are not covered by the first organic layer 210 and may extend along the top surface of the first organic layer 210 and the contact electrode CTE.

The connection electrodes BE1 and BE2 may include molybdenum (Mo), aluminum (Al), chromium (Cr), gold (Au), titanium (Ti), nickel (Ni), neodymium (Nd), and/or copper (Cu). Alternatively, the connection electrodes BE1 and BE2 may be made of a transparent conductive material (TCO) such as indium tin oxide (ITO) and/or indium zinc oxide (IZO).

The connection electrodes BE1 and BE2 may be arranged on the side surfaces of the plurality of semiconductor layers STC. Among the side surfaces of the plurality of semiconductor layers STC, an area adjacent to the top surfaces of the plurality of semiconductor layers STC may be exposed without being covered by the connection electrodes BE1 and BE2. For example, the distance between the top surfaces of the plurality of semiconductor layers STC and the connection electrodes BE1 and BE2 in the third direction DR3 may be greater than approximately 100 nm. Furthermore, the distance between the top surfaces of the plurality of semiconductor layers STC and the connection electrodes BE1 and BE2 in the third direction DR3 may be greater than a maximum length of the light extraction pattern in the third direction DR3.

In the third direction DR3, the separation distance between the top surfaces of the plurality of semiconductor layers STC and the connection electrodes BE1 and BE2 may be greater than the separation distance between the top surfaces of the plurality of semiconductor layers STC and the contact electrodes CTE in the third direction DR3, but the embodiment of the present disclosure is not limited thereto. For example, the separation distance between the top surfaces of the plurality of semiconductor layers STC and the connection electrodes BE1 and BE2 in the third direction DR3 may be smaller than the separation distance between the top surfaces of the plurality of semiconductor layers STC and the contact electrodes CTE in the third direction DR3. In this case, the connection electrodes BE1 and BE2 may cover at least a portion of the protective film INS that is exposed and not covered by the contact electrodes CTE. Alternatively, the connection electrodes BE1 and BE2 may be arranged to cover the entirety of the protective film INS that is exposed and not covered by the contact electrodes CTE. As another example, the distance between the top surfaces of the plurality of semiconductor layers STC and the connection electrodes BE1 and BE2 in the third direction DR3 may be substantially the same as the distance between the top surfaces of the plurality of semiconductor layers STC and the contact electrode CTE in the third direction DR3.

A via layer VIA may cover a portion of the side surface of the light emitting element LE. The height of the via layer VIA may be higher than the height of the contact electrode CTE. That is, the via layer VIA may be arranged to cover the contact electrode CTE arranged on the side surface of the light emitting element LE.

The via layer VIA may be formed of an organic film such as an acrylic resin, an epoxy resin, a phenolic resin, a polyamide resin, a polyimide resin, and/or the like.

A common electrode CE may be arranged on the top surface of each of the plurality of light emitting elements LE and the top surface of the via layer VIA. The common electrode CE may be a common layer formed commonly on the first sub-pixel SPX1, the second sub-pixel SPX2, and the third sub-pixel SPX3. The common electrode CE may be made of a transparent conductive material (TCO) such as indium tin oxide (ITO) and/or indium zinc oxide (IZO) that may transmit light.

A partition wall PW that divides each light emitting region may be arranged on the common electrode CE.

The partition wall PW may define each light emitting area. The partition wall PW is arranged to extend in the first direction DR1 and the second direction DR2 and may be formed in a grid-shaped pattern throughout the display area DA. Further, the partition wall PW does not overlap with a plurality of light emitting areas and may overlap with a non-light emitting area.

A second organic layer 211 covering the light emitting element LE may be filled inside the space formed by the partition wall PW.

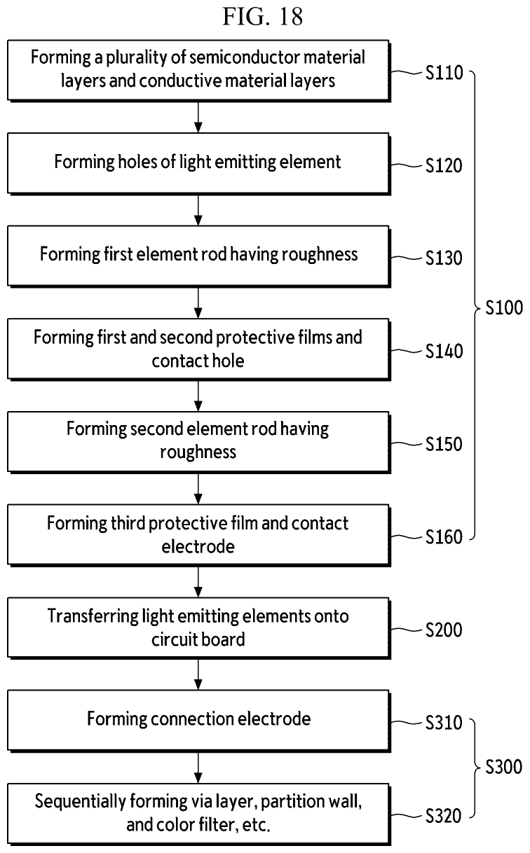

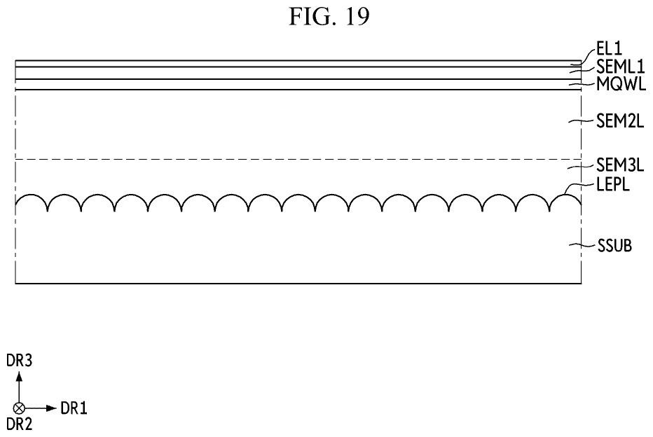

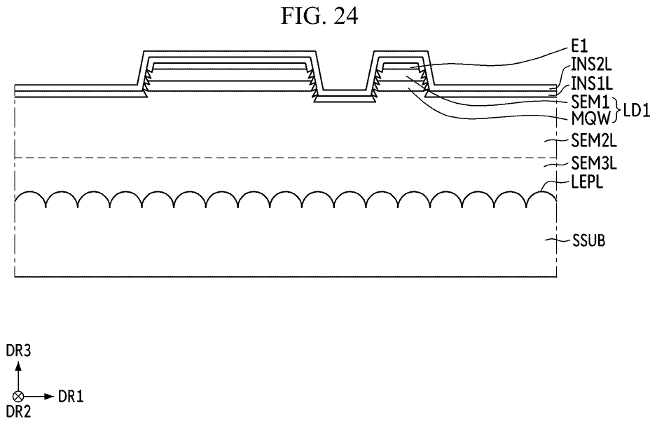

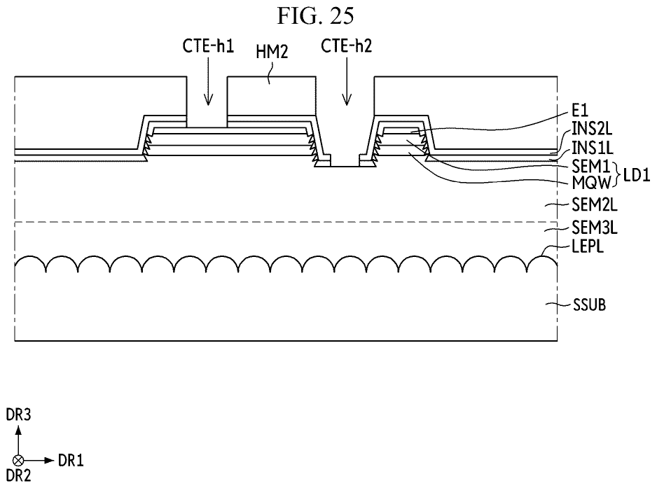

FIG. 18 is a flowchart illustrating a method of manufacturing a display device according to one or more embodiments. FIG. 19-31 are example drawings illustrating a method of manufacturing a display device according to one or more embodiments.

Hereinafter, a method for manufacturing a display device according to one or more embodiments will be described in detail by connecting FIG. 18 with FIG. 19 31. In FIG. 19-31, cross-sections corresponding to the line I1-I1′ of FIG. 6 are illustrated for convenience of explanation.

The method for manufacturing a display device may largely include forming a light emitting element LE (S100), transferring a light emitting element LE (S200), and sequentially forming connection electrodes BE1 and BE2, a via layer VIA, a partition wall PW, and a color filter CF (S300).

First, a second semiconductor material layer SEM2L, an active material layer MQWL, a first semiconductor material layer SEML1, and a conductive material layer EL1 are formed on a semiconductor substrate SSUB. (S110 in FIG. 18)

A plurality of semiconductor layers STC are elements grown on a semiconductor substrate SSUB and may be light emitting elements LE described with reference to FIG. 6-8 may be formed.

The semiconductor substrate SSUB may be a silicon wafer substrate or a sapphire substrate. A light extraction pattern LEP is formed on one surface of the semiconductor substrate SSUB. The light extraction pattern LEP may include convex patterns formed into a hemisphere or a semi-ellipse. The light extraction pattern LEP may include convex patterns having a cross-sectional shape of a semicircle or a semi-ellipse. The light extraction pattern LEP may be formed of a semiconductor material layer, an organic film, or an inorganic film.

Then, a third semiconductor material layer SEM3L is formed on the light extraction pattern LEP. Due to the light extraction pattern LEP, light extraction patterns (LEP in FIG. 19) may be formed on one surface of the third semiconductor material layer SEM3L. Then, a second semiconductor material layer SEM2L is formed on the third semiconductor material layer SEM3L. The second semiconductor material layer SEM2L may be a semiconductor material layer doped with a second conductivity type dopant such as silicon (Si), germanium (Ge), tin (Sn), and/or the like. An active material layer MQWL is formed on the second semiconductor material layer SEM2L, and a first semiconductor material layer SEML1 is formed on the active material layer MQWL. The active material layer MQWL may include the same semiconductor material layer as the first semiconductor material layer SEML1 and the second semiconductor material layer SEM2L. For example, when the first semiconductor material layer SEML1 and the second semiconductor material layer SEM2L include gallium nitride (GaN), the active material layer MQWL may also include gallium nitride (GaN). For example, the active material layer MQWL may include gallium nitride (GaN), indium gallium nitride (InGaN), and/or aluminum gallium nitride (AlGaN). The first semiconductor material layer SEML1 may be a semiconductor material layer doped with a first conductive dopant, such as magnesium (Mg), zinc (Zn), calcium (Ca), strontium (Sr), barium (Ba), and/or the like.

The light extraction pattern layer LEPL, the third semiconductor material layer SEM3L, the second semiconductor material layer SEM2L, the active material layer MQWL, and the first semiconductor material layer SEML1 may be formed on a semiconductor substrate SSUB through an epitaxial growth process. As the epitaxial growth process, electron beam deposition, physical vapor deposition (PVD), chemical vapor deposition (CVD), plasma laser deposition (PLD), dual-type thermal evaporation, sputtering, metal organic chemical vapor deposition (MOCVD), and/or the like may be used. Preferably, a metal-organic chemical vapor deposition (MOCVD) method may be used, but the present disclosure is not limited thereto.

Then, a conductive material layer EL1 is formed on the first semiconductor material layer SEML1. The conductive material layer EL1 may be formed of one of molybdenum (Mo), aluminum (Al), chromium (Cr), gold (Au), titanium (Ti), nickel (Ni), neodymium (Nd), and/or copper (Cu).

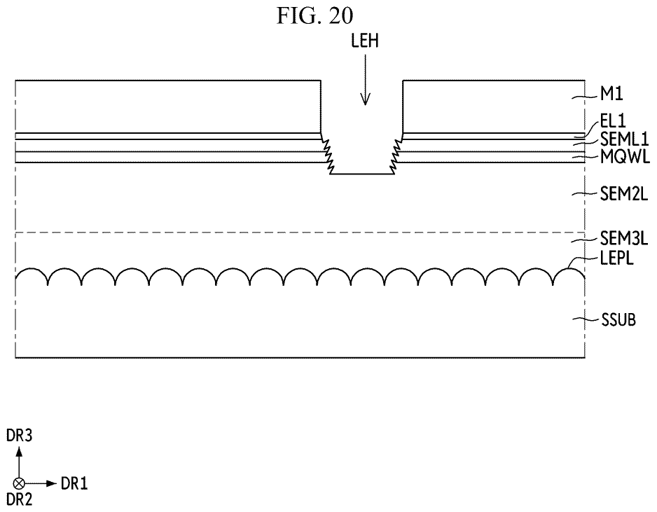

Second, as shown in FIG. 20, a hole LEH is formed. (S120 in FIG. 18)

After forming a mask pattern M1 on the conductive material layer EL1, a hole LEH is formed that penetrates the conductive material layer EL1, the first semiconductor material layer SEML1, and the active material layer MQWL in each of the light emitting elements LE to expose the second semiconductor material layer SEM2L.

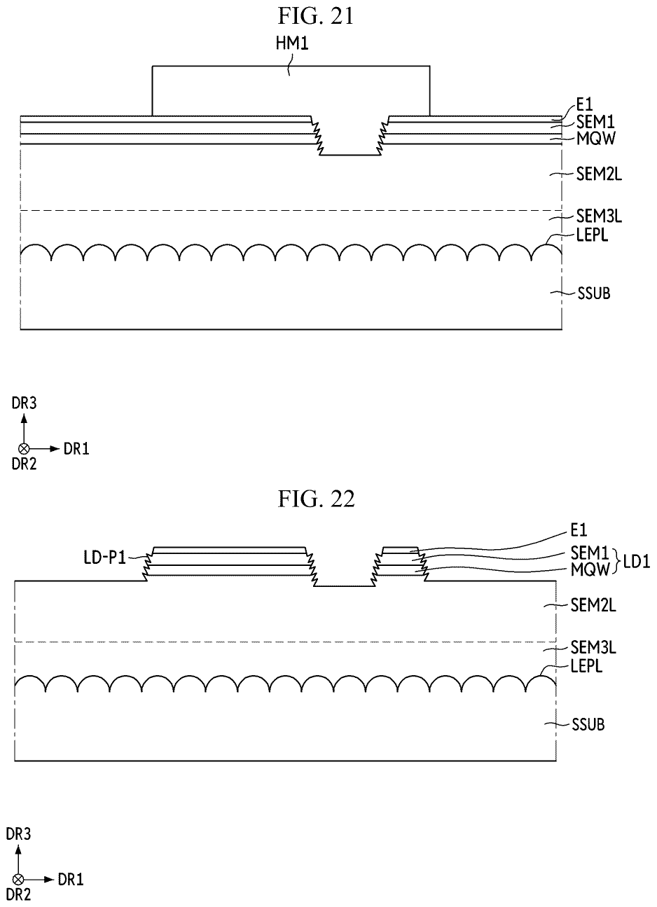

Third, as shown in FIGS. 21 and 22, a first element rod LD1 having a roughness is formed. (S130 in FIG. 18)

For example, referring to FIGS. 19-22, at least the first semiconductor material layer SEM1L and the active material layer MQWL of each light emitting element are dry-etched using the first mask HM1. At this time, a portion of the second semiconductor material layer SEM2L may be further etched.

As the etching depth increases during dry etching, the process time also increases, and the plasma exposure time of the semiconductor material layer becomes longer, which may cause damage to the active layer MQW. Therefore, in one or more embodiments, instead of etching the first semiconductor material layer SEM1L, the active material layer MQWL, the second semiconductor material layer SEM2L, and the third semiconductor material layer SEM3L at once, only a portion of the first semiconductor material layer SEM1L, the active material layer MQWL, and the second semiconductor material layer SEM2L, corresponding to about 1/10 of the entire semiconductor material layer, is etched. Therefore, damage to the active layer may be reduced or minimized.

Then, the first element rod LD1 is wet-etched.

During the wet-etching, for example, by dipping in a basic solvent such as tetramethylammonium hydroxide (TMAH) or potassium hydroxide (KOH), a fine roughness in the form of protrusions may be formed on the side surface of the first element rod LD1. The protrusion LD-P1 formed in this way may have a cross-section such as a triangular pyramid, a square pyramid, or a cone, as shown in FIGS. 21-22. Alternatively, the protrusion may have an irregular pattern.

At this time, the first mask HM1 is a hard mask and may have an arbitrary thickness. For example, when the thickness of the hard mask is about 0.25 um, roughness may not be formed on the side surface. On the other hand, when the thickness of the hard mask is 1.5 um, roughness may be formed on the side surface. In this way, the roughness on the side surface may or may not be formed depending on the thickness of the hard mask. The value may vary depending on the size of the light emitting element and the etchant.

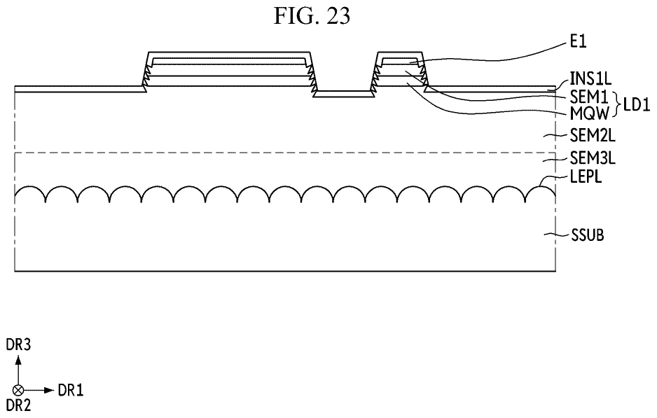

Fourth, referring to FIG. 23-25, protective films INS1 and INS2 and contact holes CTE-h1 and CTE-h2 surrounding the first element rod LD1 are formed. (S140 in FIG. 18)

After forming the first protective film layer INS1L on the first element rod LD1, a second protective film layer INS2L is formed on the first protective film layer INS1L. The first protective film layer INS1L may be around (e.g., may surround) one side and a side surface of the first element rod LD1, and the second protective film layer INS2L may be around (e.g., may surround) one side and a side surface of the first element rod LD1 outside the first protective film layer INS2L.

Then, a first contact hole CTE-h1 and a second contact hole CTE-h2 overlapping one side of the first element rod LD1 are formed using a second mask HM2. The first protective layer INS1L and the second protective layer INS2L that do not overlap with the second mask HM2 are etched to form the first contact hole CTE-h1 that exposes one surface of the conductive layer E1 and a second contact hole CTE-h2 that exposes one surface of the second semiconductor layer SEM2. The depths of the first contact hole CTE-h1 and the second contact hole CTE-h2 are different from each other. Therefore, in one or more embodiments, after the first contact hole CTE-h1 is created, a protective mask or the like that protects the first contact hole CTE-h1 may be formed, and then the second contact hole CTE-h2 may be formed. Thereafter, the second mask HM2 may be removed.

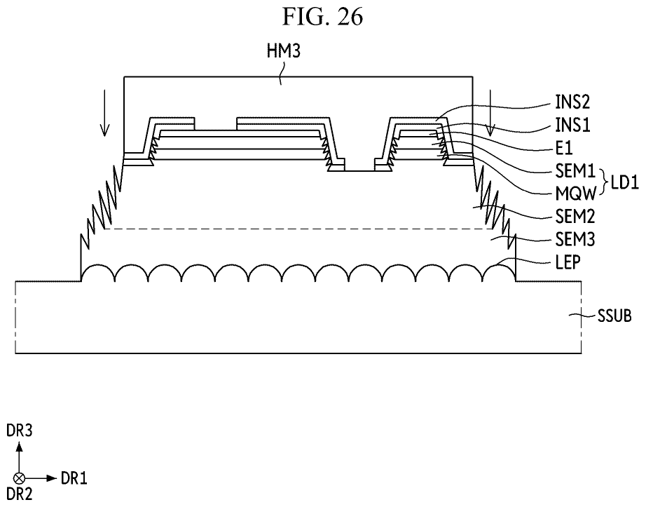

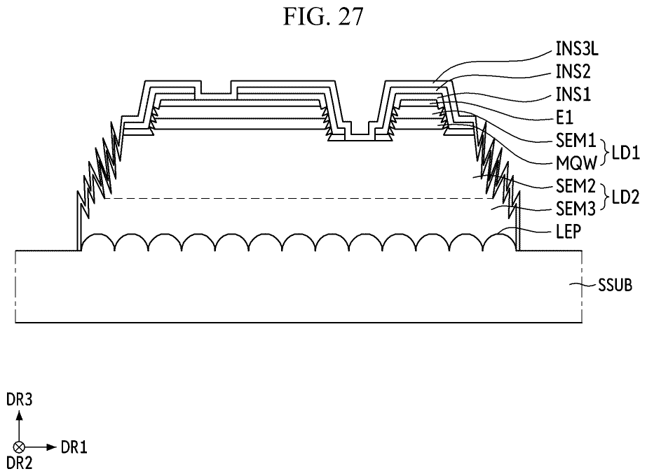

Fifth, referring to FIGS. 26 and 27, a second element rod LD2 having a roughness may be formed. (S150 in FIG. 18)

After forming a third mask HM3 to surround the first element rod LD1, a second semiconductor material layer SEM2L and a third semiconductor material layer SEM3L are patterned using the patterned hard mask HM3 as a mask. For example, the second semiconductor material layer SEM2L and the third semiconductor material layer SEM3L may be formed into a second semiconductor layer SEM2 and a third semiconductor layer SEM3 through a dry etching process. The hard mask HM3 may be formed of a silicon oxide system (SiOₓ) as a hard mask. At this time, the etching may be wet etching or dry etching.

In the case of dry etching, protrusions having a shape such as a triangular pyramid, a square pyramid, or a cone may be formed on both sides of the light emitting element LE corresponding to the second region and the third region.

In one or more embodiments, as shown in FIG. 10, protrusions having an irregular pattern may be formed on the second semiconductor layer SEM2 and the third semiconductor layer SEM3 of the light emitting element LE in the case of wet etching. Further, patterns may be formed concurrently (e.g., simultaneously) on the second region and the third region. In this case, protrusions having an irregular pattern may be formed on both sides of the light emitting element LE corresponding to the second region and the third region.

In one or more embodiments, additional wet etching of the second region may be performed after dry etching the second region and the third region. In this case, as shown in FIG. 11, a protrusion having an irregular pattern is formed on the side of the light emitting element LE corresponding to the second region, and a protrusion having a shape such as a triangular pyramid, a square pyramid, or a cone may be formed on the side of the light emitting element LE corresponding to the first region and the second region.

The inclination of the side of the second semiconductor layer SEM2 and the third semiconductor layer SEM3 may be smaller than that of the first element rod LD1. Therefore, the width may become wider from the second semiconductor layer SEM2 toward the third semiconductor layer SEM3.

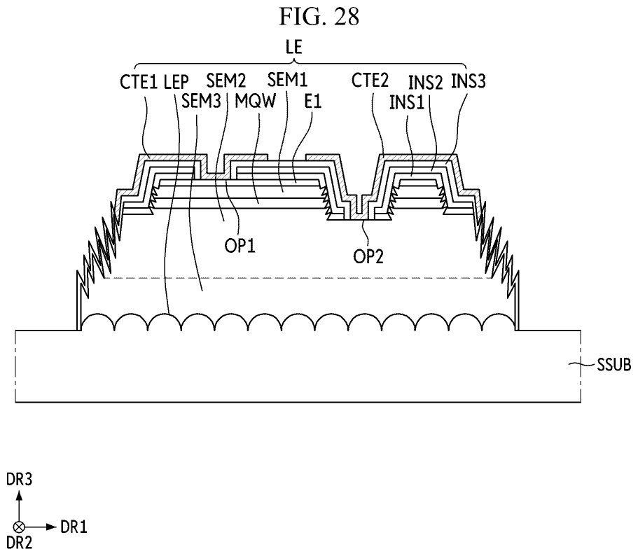

Referring to FIG. 28, a third protective film INS3 and contact electrodes CTE1 and CTE2 are formed. (S160 in FIG. 18)

A third protective film INS3 is formed to be around (e.g., to surround) the first element rod LD1 and the second element rod LD2. The third protective film INS3 may be formed of an inorganic film, such as, a silicon nitride layer, a silicon oxynitride layer, a silicon oxide layer, a titanium oxide layer, and/or an aluminum oxide layer but is not limited thereto.

A first opening OP1 and a second opening OP2 are formed on the third protective film INS3. The first opening OP1 exposes the conductive layer E1, and the second opening OP2 exposes the second semiconductor layer SEM2.

A contact electrode layer CTEL is deposited on one side of the first element rod LD1 and the second element rod LD2. The contact electrode layer CTEL may include at least one of gold (Au), copper (Cu), tin (Sn), silver (Ag), aluminum (Al), and titanium (Ti).

The contact electrode layer CTEL is partially etched to form a first contact electrode CTE1 and a second contact electrode CTE2 that are spaced (e.g., spaced apart) from each other.

The first contact electrode CTE1 directly contacts the conductive layer E1 through the first opening OP1, and the second contact electrode CTE2 directly contacts the second semiconductor layer SEM2 through the second opening OP2.

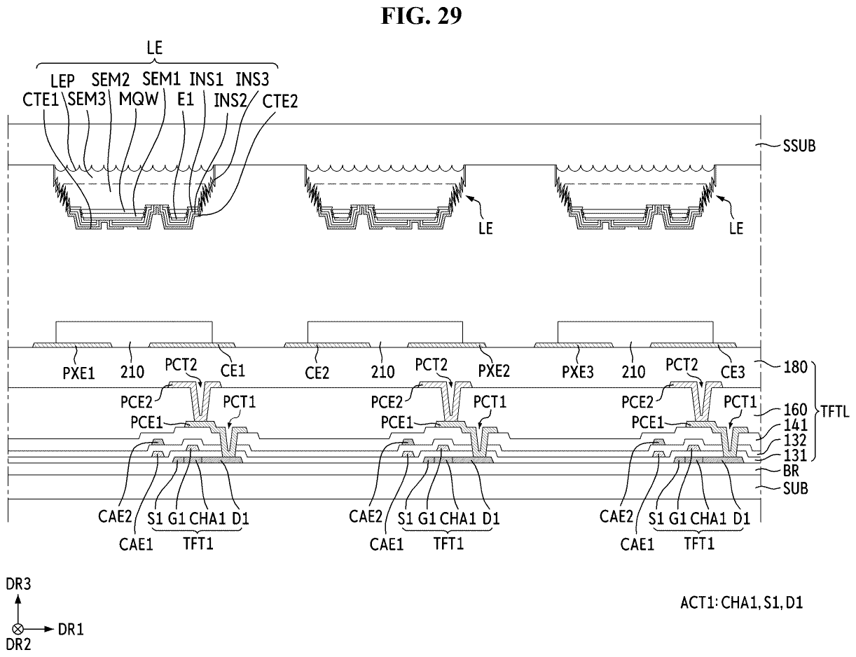

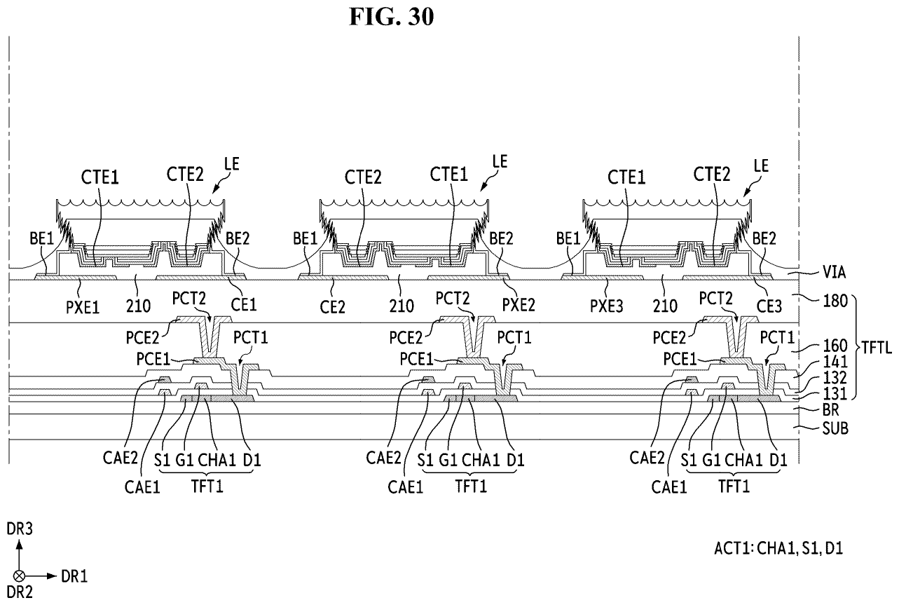

Then, referring to FIGS. 29 and 30, the light emitting elements LE are transferred onto the circuit board. (S200 in FIG. 18)

For convenience of explanation, the light emitting elements LE on the semiconductor substrate SSUB are transferred onto the circuit board as an example, but the light emitting elements LE on the semiconductor substrate SSUB may be transferred multiple times using a relay substrate and/or the like and then transferred onto the circuit board. Alternatively, they may be transferred onto the circuit board using a stamp and/or the like.

The first element rod LD1 of the light emitting elements LE is aligned so that it is positioned on the first organic layer 210. Then, the semiconductor substrate SSUB is separated from the light emitting elements LE and removed. For example, the plurality of light emitting elements LE may be separated from the semiconductor substrate SSUB by a laser lift off (LLO) process. At this time, the light emitting elements LE may be temporarily fixed by being embedded in the first organic layer 210. When the first organic layer 210 is a photosensitive organic film such as a photoresist, after the first organic layer 210 is hardened (soft baked) at a first temperature, at least a portion of each of the plurality of light emitting elements LE is inserted into the first organic layer 210. Then, the first organic layer 210 may be completely hardened at a second temperature higher than the first temperature. The first temperature may be approximately 100 degrees, and the second temperature may be approximately 230 degrees, but the present disclosure is not limited thereto. Furthermore, the process of completely hardening the first organic layer 210 at the second temperature may be performed for approximately 30 minutes.

Thereafter, referring to FIG. 30, connection electrodes BE1 and BE2 connecting the contact electrode CTE of the light emitting element LE and the pixel electrode layer is formed. (S310 in FIG. 18)

For example, a connection electrode layer covering the pixel electrodes PXE1, PXE2, and PXE3, the common electrodes CE1, CE2, and CE3, the first organic layer 210, and the light emitting element LE is formed. Then, a via layer VIA covering the electrodes PXE1, PXE2, and PXE3, the common electrodes CE1, CE2, and CE3, the first organic layer 210, and a portion of the light emitting element LE is formed. As shown in FIG. 7, the via layer VIA may be formed to surround the first region LD-1Z and the second region LD-2Z of the light emitting element LE.

Using the via layer VIA as a mask, a portion of the connection electrode layer is etched to form a first connection electrode BE1 covering the side surface of the pixel electrode PXE1, PXE2, and PXE3, the first organic layer 210, and the light emitting element LE, and a second connection electrode BE2 covering the side surface of the common electrodes CE1, CE2, and CE3, the first organic layer 210, and the light emitting element LE.

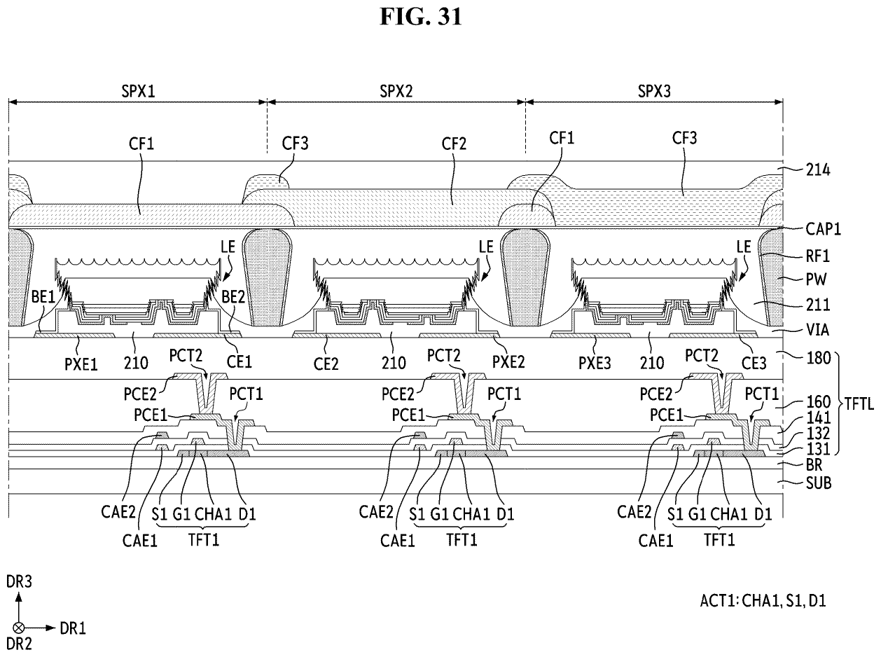

Referring to FIG. 31, the second organic layer 211, the partition wall PW, and the color filters CF1, CF2, and CF3 are sequentially formed. (S320 in FIG. 18)

The partition wall PW is formed so as not to overlap with the light emitting elements LE in the third direction DR3 on the via layer VIA.

A reflective layer RF1 may be formed on the side surface of the partition wall PW. Then, the second organic layer 211 is filled to cover the light emitting element LE and the via layer VIA in the space formed by the partition wall PW, thereby flattening the step formed by the light emitting element LE.

A capping layer CAP1 is formed on the second organic layer 211 and the partition wall PW, and then the first color filter CF1, the second color filter CF2, and the third color filter CF3 are formed. For example, the first color filter CF1 is formed to overlap the first sub-pixel SPX1 in the third direction DR3, the second color filter CF2 is formed to overlap the second sub-pixel SPX2 in the third direction DR3, and the third color filter CF3 is formed to overlap the third sub-pixel SPX3 in the third direction DR3.

Then, a fifth organic film 214 is formed on the first color filter CF1, the second color filter CF2, and the third color filter CF3.

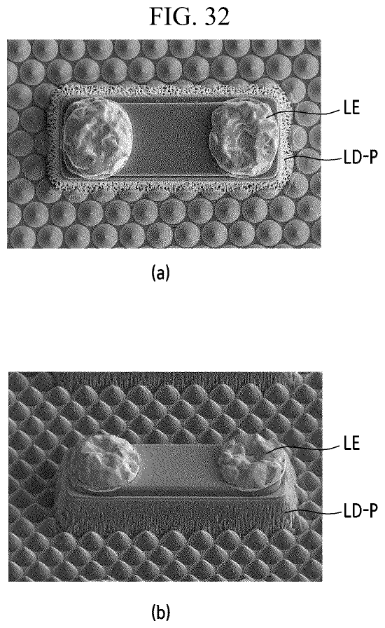

FIG. 32 is a photograph of a plan view and a perspective view of a light emitting element formed with reference to FIG. 18-31.

FIG. 32 (a) is a plan view of a light emitting element LE, and FIG. 32 (b) is a perspective view of the light emitting element LE. Referring to FIG. 32 (a) and (b), a roughness pattern of a fine protrusion LD-P pattern is formed on the side of the light emitting element LE. The degree of roughness may vary depending on the height of the light emitting element LE.

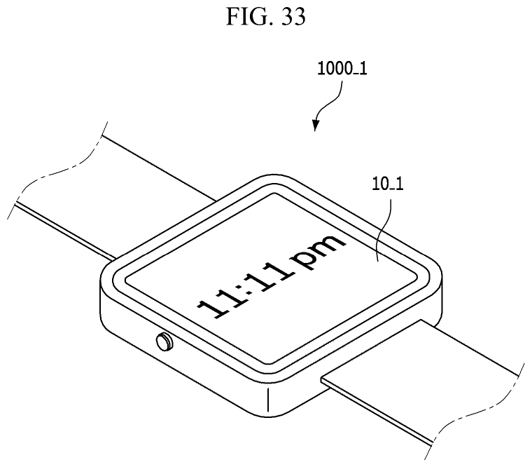

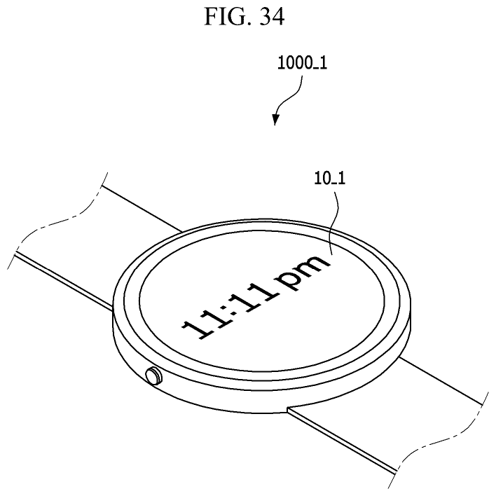

FIGS. 33 and 34 are example drawings illustrating a smart watch including a display device according to one or more embodiments.

Referring to FIGS. 33 and 34, a display device 10_1 according to one or more embodiments may be applied to a smart watch 1000_1, which is one of smart devices.

The flat shape of the display device 10_1 may be a square or a circle but is not limited thereto and may be modified in various ways, such as an oval.

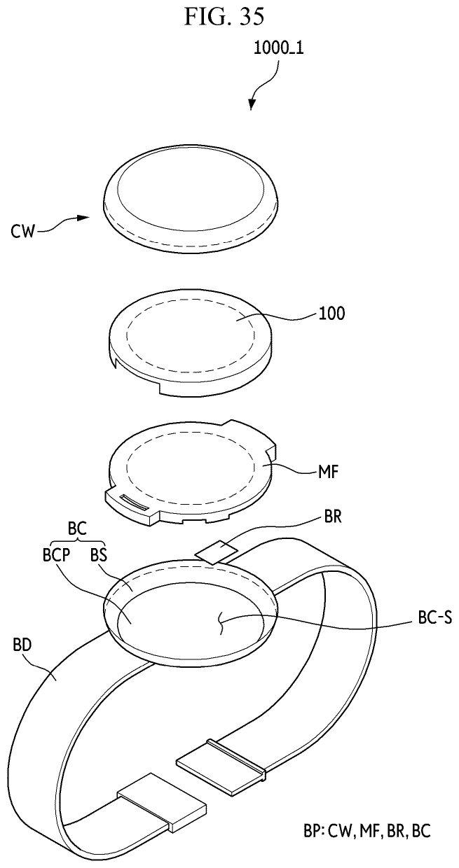

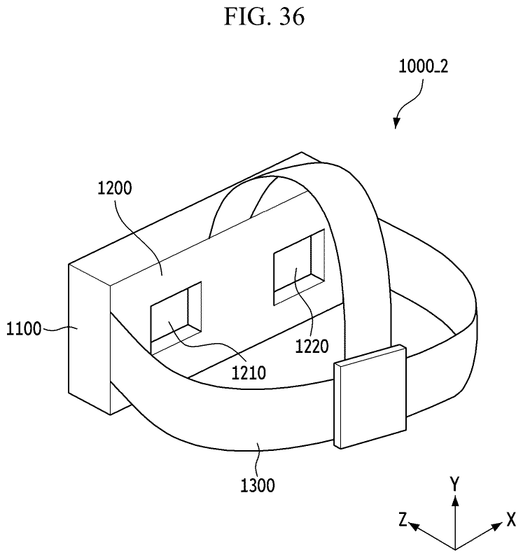

FIG. 35 is an exploded perspective view of a smart watch including a display device according to one or more embodiments.

Referring to FIG. 35, the smart watch 1000_1 may include a main body unit BP and a wearable portion BD.

The main body unit BP may include a display panel 100 on which an image is displayed, a cover window CW disposed on the display panel 100, a bottom cover BC disposed under the display panel 100, a middle frame MF disposed between the cover window CW and the bottom cover BC, and a battery BR disposed between the middle frame MF and the bottom cover BC. In addition to the battery BR, a main processor controlling the smart watch 1000_1, a communication chipset for wirelessly communicating with the outside, and a circuit board in which memory, etc. are mounted may be additionally arranged between the middle frame MF and the bottom cover BC.

The main body unit BP may sequentially include a bottom cover BC, a battery BR, a middle frame MF, a display panel 100, and a cover window CW.

The cover window CW is arranged on the upper portion of the display panel 100 to protect the display panel 100 and to transmit light emitted from the display panel 100. As described above, the cover window CW may include a light-blocking portion to block a portion of the light emitted from the display panel 100. The cover window CW may be made of a transparent plastic material, a glass material, or a reinforced glass material.

The cover window CW may be arranged to overlap the display panel 100 and cover the front of the display panel 100. The cover window CW generally has a shape similar to that of the display panel 100 in terms of a plane, but its size may be larger than that of the display panel 100. For example, the cover window CW may protrude outward from the display panel 100. The plane shape of the cover window CW may be the same as that of the main body unit BP. For example, the planar shape of the cover window CW may be generally circular but is not limited thereto and may have various shapes, for example, a polygon such as a square or an oval.

The middle frame MF is a joining member for joining the cover window CW and the bottom cover BC and is arranged between the cover window CW and the bottom cover BC. For example, the middle frame MF may include a bracket.

The bottom cover BC is a housing arranged under the display panel 100.

The bottom cover BC may include a central cover portion BCP and a peripheral portion BS arranged around the central cover portion BCP.

The central cover portion BCP is located at the center of the bottom cover BC and may be generally flat.

The peripheral portion BS may be arranged to be around (e.g., to surround) the central cover portion BCP. The peripheral portion BS may be a portion that is bent and curved from the central cover portion BCP. The peripheral portion BS may be bent from the edge of the central cover portion BCP. In some embodiments, the peripheral portion BS may include a curved surface having a suitable curvature (e.g., a predetermined curvature), and the other portion may be flat. The degree (or angle) at which the peripheral portion BS is bent from the central cover portion BCP may be an obtuse angle, but is not limited thereto, and may also be a right angle or an acute angle.

A storage space BC-S may be formed by the central cover portion BCP and the peripheral portion BS. A battery BR may be placed in the storage space BC-S.

The battery BR may be connected to a circuit board on which a main processor or the like is mounted. The display device 10_1 may be electrically connected to the circuit board to receive digital video signals, timing signals, power, and the like.

The bottom cover BC is placed on the outermost rear surface of the electronic device and may include at least one of a plastic material, a metal material, and a glass material, and may include a color coating layer. For example, the bottom cover BC according to one example may be a flat glass having a transparent, translucent, or opaque color coating layer.

The bottom cover BC according to another example may have the same shape as the cover window CW and may include a glass material having a color coating layer. For example, the bottom cover BC according to another example may have a structure symmetrical to the cover window CW with a middle frame MF in between and may include a transparent, translucent, or opaque color coating layer.

The wearing portion BD is a portion for fixing the main body unit BP to the user's wrist, for example, and may be one of a strap, a chain, and a bracelet.

FIG. 36 is example views of a virtual reality (VR) device including a display device according to one or more embodiments.

Referring to FIG. 36, a head mounted display device 1000_2 according to one or more embodiments includes a display device housing 1100, a housing cover 1200, a first eyepiece 1210, a second eyepiece 1220, and head mounted band 1300.

The display device housing 1100 houses a display device. A head mounted display device 1000_2 according to one or more embodiments further include a first optical member disposed between the first display device and the first eyepiece 1210.

The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIG. 36, the present disclosure is not limited thereto. The first eyepiece 1210 and the second eyepiece 1220 may also be combined into one.

The head mounted band 1300 fixes the display device housing 1100 to a user's head so that the first eyepiece 1210 and the second eyepiece 1220 of the housing cover 1200 are kept placed on the user's left and right eyes, respectively. When the housing cover 1200 is implemented to be lightweight and small, the head mounted display device 1000_2 may include an eyeglass frame as illustrated in FIG. 36 instead of the head mounted band 1300.

The display device housing 1100 houses display device. In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, and/or a Bluetooth module.

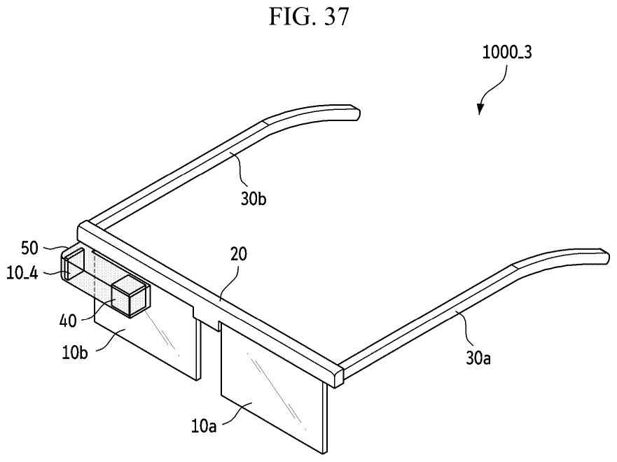

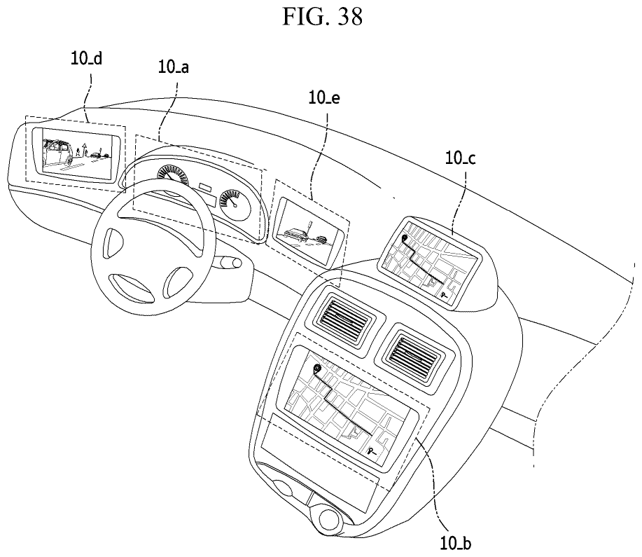

FIG. 37 is an example view of a VR device including a display device according to one or more embodiments. FIG. 37 illustrates a VR device 1000_3 to which a display device 10_4 according to one or more embodiments has been applied.

Referring to FIG. 37, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 37, a case where the VR device 1000_3 is a glasses-type display device including the eyeglass frame legs 30a and 30b is illustrated as an example. That is, the VR device 1000_3 according to the embodiment is not limited to the one illustrated in FIG. 37 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 37, the present disclosure is not limited thereto. For example, the display device housing 50 may also be disposed at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

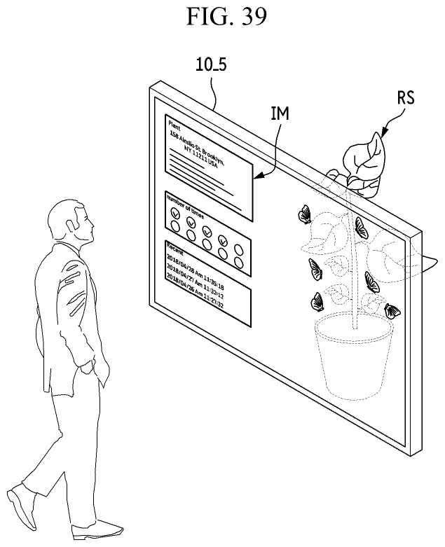

FIG. 38 is an example view illustrating a vehicle instrument cluster and center fascia including display devices according to one or more embodiments. FIG. 26 illustrates a vehicle to which display devices 10_a through 10_e according to one or more embodiments have been applied.

Referring to FIG. 38, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

FIG. 39 is an example view of a transparent display device including a display device according to one or more embodiments.

Referring to FIG. 39, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
a first pixel electrode and a second common electrode spaced from each other on the substrate; and
a light emitting element on the first pixel electrode and the second common electrode, the light emitting element having a plurality of roughness patterns on a side surface,
wherein the light emitting element is divided into a plurality of regions along a direction perpendicular to the substrate, and sizes of the plurality of roughness patterns in the plurality of regions are different from each other.

2. The display device of claim 1, wherein the plurality of regions comprise a first region and a second region,
wherein the light emitting element comprises a first semiconductor layer, an active layer, and a second semiconductor layer,
wherein the first region comprises the first semiconductor layer and the active layer, and
wherein a size of a roughness pattern of the first region is smaller than a size of a roughness pattern of the second region.

3. The display device of claim 2, wherein the plurality of regions further comprise a third region,
wherein the first region, the second region, and the third region are arranged sequentially, and
wherein the sizes of the plurality of roughness patterns increases from the first region to the third region.

4. The display device of claim 3, wherein the size of the roughness pattern of the first region is 1 μm or less,
wherein the size of the roughness pattern of the second region is more than 1 μm and 3 μm or less, and
wherein a size of the roughness pattern of the third region is 3 μm or more.

5. The display device of claim 1, wherein the plurality of roughness patterns has a protrusion shape that becomes thinner toward outside, or has an irregular pattern shape in which a width and a height of the protrusion shape are randomly distributed.

6. The display device of claim 2, wherein a shape of the roughness pattern of the first region and a shape of the roughness pattern of the second region are different from each other.

7. The display device of claim 2, wherein the light emitting element comprises:
a plurality of semiconductor layers;
a first contact electrode extending laterally from one surface of the light emitting element; and
a second contact electrode extending laterally from the one surface of the light emitting element, the second contact electrode being spaced from the first contact electrode,
wherein the first contact electrode and the second contact electrode are in the first region and the second region.

8. The display device of claim 7, further comprising:
an organic layer between the light emitting element, and the first pixel electrode and the second common electrode;
a first connection electrode electrically connecting the first pixel electrode and the first contact electrode; and
a second connection electrode electrically connecting the second common electrode and the second contact electrode.

9. The display device of claim 7, wherein the light emitting element further comprises:
a conductive layer on an element planarization layer; and
a protective film on one surface and side surfaces of the conductive layer and side surfaces of the plurality of semiconductor layers,
wherein the first contact electrode is on the protective film and is connected to the conductive layer exposed without being covered by the protective film, and
wherein the second contact electrode is on the protective film and is located in a hole penetrating the conductive layer and a portion of the plurality of semiconductor layers.

10. The display device of claim 8, wherein a side corresponding to the first region of the light emitting element is surrounded by the organic layer, and at least a portion of the side is outside the organic layer.

11. The display device of claim 8, further comprising a via layer covering the first connection electrode and the second connection electrode,
wherein the first region and the second region are surrounded by the via layer.

12. The display device of claim 1, wherein a top surface of the light emitting element has a concave pattern light extraction pattern having a cross-sectional shape of a semicircle or a semi-ellipse.

13. A method for manufacturing a display device comprising a light emitting element, the method comprising:
forming a third semiconductor material layer, a second semiconductor material layer, an active material layer, a first semiconductor material layer, and a conductive material layer on a semiconductor substrate;
etching the active material layer, the first semiconductor material layer, and the conductive material layer to form a first element rod having a first roughness pattern on a side surface;
forming a protective film to protect the first element rod;
forming a mask covering the first element rod and etching the second semiconductor material layer and the third semiconductor material layer to form a second element rod having a second roughness pattern; and
forming a first contact electrode and a second contact electrode extending laterally from one surface of the first element rod, the first contact electrode and the second contact electrode being spaced from each other,
wherein a size of the second roughness pattern is different from a size of the first roughness pattern.

14. The method of claim 13, wherein a size of the first roughness pattern is smaller than a size of the second roughness pattern.

15. The method of claim 13, wherein the first roughness pattern and the second roughness pattern have a protrusion shape that becomes thinner toward outside or have an irregular pattern shape in which a width and height of the protrusion shape are randomly distributed.

16. The method of claim 13, wherein the first element rod is formed by wet etching, and
wherein the second element rod is formed by wet etching or dry etching.

17. The method of claim 13, further comprises:
transferring the light emitting element to a backplane substrate so that the first contact electrode and the second contact electrode face a pixel electrode and a common electrode of the backplane substrate;
forming a first connection electrode connecting the pixel electrode and the first contact electrode of the light emitting element, and a second connection electrode connecting the common electrode and the second contact electrode of the light emitting element; and
forming a via layer covering the first connection electrode and the second connection electrode.

18. The method of claim 17, wherein an organic layer is formed on the pixel electrode and the common electrode of the backplane substrate,
wherein the side surface of the first element rod is buried in the organic layer, a portion of a side surface of the first contact electrode of the light emitting element and a portion of a side surface of the second contact electrode are embedded in the organic layer, and a remaining portion of the side surface of the first contact electrode and a remaining portion of the side surface of the second contact electrode are not covered by the organic layer.

19. The method of claim 18, wherein the first connection electrode is connected to a remaining portion of the side surface of the first contact electrode, and the second connection electrode is connected to a remaining portion of the side surface of the second contact electrode.

20. An electronic device comprising:
a display panel;
a window arranged on the display panel; and
a bottom cover arranged below the display panel,
wherein the display panel comprises:
a substrate;
a first electrode and a second electrode spaced from each other on the substrate; and
a light emitting element on the first electrode and the second electrode, the light emitting element having a plurality of roughness patterns on a side surface,
wherein the light emitting element is divided into a plurality of regions along a direction perpendicular to the substrate, and sizes of the roughness patterns in the plurality of regions are different from each other.
